(19) United States
(12) Patent Application Publication
(10) Pub. No.: US 2025/0262689 A1
(43) Pub. Date: Aug. 21, 2025

(54) METHODS FOR PEROVSKITE INTRAGRAIN IMPURITY REDUCTION

(71) Applicant: The Hong Kong University of Science and Technology, Hong Kong (CN)

(72) Inventor: Yuanyuan ZHOU, Hong Kong (CN)

(21) Appl. No.: 19/044,716

(22) Filed: Feb. 4, 2025

Related U.S. Application Data
(60) Provisional application No. 63/555,910, filed on Feb. 21, 2024.

(51) Int. Cl. B23K 26/16

(52) U.S. Cl. CPC B23K 26/16

(57) ABSTRACT

A method of reducing intragrain impurities in a perovskite, the method comprising: irradiating the perovskite with an energy beam selected from the group consisting of a laser beam and an electron beam thereby reducing the intragrain impurities in the perovskite. The intragrain impurities can include (M²⁺)(X⁻)₂ and (A⁺)(X⁻); and the perovskite includes a Formula (A⁺)(M²⁺)(X⁻)₃, wherein M²⁺ includes Pb²⁺, Sn²⁺, Ge²⁺, or a mixture thereof; X⁻ includes F⁻, Cl⁻, Br⁻, I⁻, or a mixture thereof; and A⁺ includes Cs⁺, Rb⁺, CH₃NH₃⁺, CH₃CH₂NH₃⁺, H(C═NH₂)NH₂⁺, Me(C═NH₂)NH₂⁺, or a mixture thereof.

### CROSS-REFERENCE TO RELATED APPLICATIONS

The present application claims priority from U.S. Provisional Patent Application No. 63/555,910, filed on Feb. 21, 2024, which is hereby incorporated by reference in its entirety.

### STATEMENT REGARDING PRIOR DISCLOSURES BY THE INVENTORS OR JOINT INVENTORS UNDER 37 CFR 1.77(b)(6)

Part of the present invention was disclosed in a paper published in Cai, S., Li, Z., Zhang, Y. et al. Intragrain impurity annihilation for highly efficient and stable perovskite solar cells, Nat Commun 15, 2329 (2024). This paper is a grace period inventor-originated disclosure disclosed within one year before the filing date of this application and falls within the exceptions defined under 35 USC § 102(b)(1). This paper is hereby incorporated by reference in its entirety.

### TECHNICAL FIELD

The present disclosure relates methods for reducing the concentration of perovskite intragrain impurities.

### BACKGROUND

Perovskite solar cells (PSCs) have attracted enormous attention in the field of photovoltaic energy due to their high power conversion efficiencies (PCEs) which rapidly reached certified 26.2%. The technological advance of PSCs has been largely driven by the development of various microstructural tailoring strategies that can reduce defects and impurities generated during the processing, post-synthesis storage and operation. Because metal halide perovskite thin films are polycrystalline in nature and are grown via typical solution crystallization routes, defects and impurities are intuitively considered to exist in the inter-grain regions. Therefore, in the past years, research effort has primarily been devoted to tailoring grain boundaries for favorable defect properties and phase distribution.

Nevertheless, there is a need for improved methods for reducing intragrain defects and impurities in perovskites.

### SUMMARY

The fundamental behaviors and effects of intragrain defects and impurities have been rarely studied, although they are known as essential to semiconductors in general. One major hurdle in this research direction is to reliably image the microstructure and dynamics of intragrain defects and impurities.

Transmission electron microscopy (TEM) is a workhorse tool for materials characterization with high spatial resolution, which has been leveraged to demonstrate unambiguous observation of atomic-scale details of perovskites. In a recent study, we reported a simple, modified scanning TEM (STEM) method in conjunction with focused ion beam (FIB) nanofabrication of perovskite sample specimen, which allows direct, reliable observation of perovskite microstructures that are embedded in PSCs. By leveraging the significant development, herein we demonstrate an in situ STEM approach to visualize the atomic-scale microstructural evolution in PSCs with a controllable, low-dose electron beam as the external energy stimulus. We found in the solution-processed formamidinium-cesium PSCs, while the grain boundaries (GBs) can exhibit pure phases, nanoscale impurity phases, primarily in the form of PbI₂, can exist in intragrain regions and within the crystalline perovskite matrix, suggesting that these PbI₂ phases are inherently formed during the solution-based fabrication and post-synthesis storage. Counterintuitively, upon the external energy stimulus (i.e. controlled STEM electron beam), these intragrain impurity phases are readily healed to perovskite via versatile crystallographic transformation pathways to perovskites, which are atomically resolved. The dynamic structural and electronic landscapes of such intragrain impurity annihilation (IGIA) are further understood using theoretical calculations based on equivalent, correlated models.

The IGIA revealed by STEM has inspired us to adopt an optimal laser stimulus to treat as-fabricated formamidinium-cesium perovskite films, which can quickly increase the PCEs. We further confirmed that the IGIA underpins the device enhancement regardless of a different stimulus type. The phase-healed perovskite grains also exhibit a more relaxed strain structure, leading to devices with high stability. More importantly, this laser treatment is adoptable to PSCs after storing to recover the device performance. We combined theoretical and experimental investigations to gain insights into the connection between our in situ observation and device treatment, pointing to a promising methodology featuring the translation of fundamental studies for improving perovskite device technologies.

In a first aspect, provided herein is a method of reducing intragrain impurities in a perovskite, the method comprising: irradiating the perovskite with an energy beam selected from the group consisting of a laser beam and an electron beam thereby reducing the intragrain impurities in the perovskite.

In certain embodiments, the intragrain impurities comprise (M²⁺)(X⁻)₂ and (A⁺)(X⁻); and the perovskite comprises a Formula (A⁺)(M²⁺)(X⁻)₃, wherein M²⁺ comprises Pb²⁺, Sn²⁺, Ge²⁺, or a mixture thereof; X⁻ comprises F⁻, Cl⁻, Br⁻, I⁻, or a mixture thereof; and A⁺ comprises Cs⁺, Rb⁺, CH₃NH₃⁺, CH₃CH₂NH₃⁺, H(C═NH₂)NH₂⁺, Me(C═NH₂)NH₂⁺, or a mixture thereof.

In certain embodiments, wherein M²⁺ comprises Pb²⁺, X⁻ is Br⁻, I⁻, or a mixture thereof, and A⁺is Cs⁺, CH₃NH₃⁺, H(C═NH₂)NH₂⁺, or a mixture thereof.

In certain embodiments, the intragrain impurities comprise PbI₂ and one or more of CH₃NH₃I, H(C═NH₂)NH₂I, and CsI.

In certain embodiments, the intragrain impurities comprise PbI₂ and one or more of CH₃NH₃I, H(C═NH₂)NH₂I, and CsI; and irradiating with the energy beam results in conversion of at least a portion of the intragrain impurities to perovskite.

In certain embodiments, the intragrain impurities have an area less than 100 nm².

In certain embodiments, the electron beam has a current of 1-10 pA.

In certain embodiments, the intragrain impurities receive an accumulated electron dose of at least 1.3×10⁵ e·Å⁻².

In certain embodiments, the intragrain impurities have an area less than 100 nm²; and the intragrain impurities receive an accumulated electron dose of at least 1.3×10⁵ e·Å⁻².

In certain embodiments, the electron beam has a current of 1-10 pA and the intragrain impurities receive an accumulated electron dose of 1×10⁵ to 1×10⁶ e·Å⁻².

In certain embodiments, the electron beam has a current of 1-10 pA and the intragrain impurities receive an accumulated electron dose of 2×10⁵ to 8×10⁵ e·Å⁻².

In certain embodiments, the laser beam has a power of 100-1,000 mW and a wavelength of 380-700 nm.

In certain embodiments, the perovskite is irradiated with the laser beam for at least one minute.

In certain embodiments, the perovskite comprises (CH₃NH₃⁺)(Pb²⁺)(I⁻)₃ or (H(C═NH₂)NH₂⁺)_{y}(Cs⁺)_{1-y}(Pb²⁺)(I⁻)₃, wherein y is 0-1; the intragrain impurities have an area less than 100 nm² and comprise PbI₂ and one or more of CH₃NH₃I, H(C═NH₂)NH₂I, and CsI; and the intragrain impurities receive an accumulated electron dose of at least 1.3×10⁵ e·Å⁻².

In certain embodiments, the perovskite comprises (CH₃NH₃⁺)(Pb²⁺)(I⁻)₃ or (H(C═NH₂)NH₂⁺)_{y}(Cs⁺)_{1-y}(Pb²⁺)(I⁻)₃, wherein y is 0-1; the intragrain impurities have an area less than 100 nm² and comprise PbI₂ and one or more of CH₃NH₃I, H(C═NH₂)NH₂I, and CsI; the electron beam has a current of 1-10 pA; and the intragrain impurities receive an accumulated electron dose of 1×10⁵ to 1×10⁶ e·Å⁻².

In certain embodiments, the perovskite is (CH₃NH₃⁺)(Pb²⁺)(I⁻), (H(C═NH₂)NH₂⁺)_{y}(Cs⁺)_{1-y}(Pb²⁺)(I⁻)₃, or a mixture thereof, wherein y is 0-1; the intragrain impurities have an area less than 100 nm² and comprise PbI₂ and one or more of CH₃NH₃I, H(C═NH₂)NH₂I, and CsI; and the laser beam has a power of 400-600 mW and a wavelength of 300-500 nm.

In certain embodiments, the perovskite is present in a photovoltaic device.

In certain embodiments, the perovskite is present in a perovskite solar cell.

In certain embodiments, the perovskite solar cell exhibits an improvement in at least one photovoltaic property selected from the group consisting of PCE, FF, J_{SC}, and V_{OC}.

### BRIEF DESCRIPTION OF THE DRAWINGS

The foregoing aspects and many of the attendant advantages of this invention will become more readily appreciated and understood by reference to the following detailed description, when taken in conjunction with the accompanying drawings.

FIG. 1. In situ STEM observation of intragrain impurity annihilation in the PSC. a, Experimental flow for in situ STEM observation: The STEM electron beam was used for structural characterization and also act as an in situ stimulus, finally, the crystallographic transition of different phases can be stimulated by high energy electron probe. b, STEM image of the starting PSC cross-sectional specimen, shows the perovskite layer consisting monolayer perovskite grains and grain boundaries. c, High-resolution STEM-HAADF image of the initial PSC sample. Solid line and dashed line regions represent impurity phases of different types that exist in the film. The

inset is the corresponding FFT pattern, indicating the [100]ₒ projection direction, scale bar: 5 nm⁻¹. d, In situ observation of transformation from PbI₂ nanocluster to perovskite phase. Atomic resolution STEM-HAADF images of orthorhombic (FA,Cs)PbI₃ nano-region projected along [100]ₒ direction contains a single PbI₂ nanocluster (marked by black dashed lines). The transformation process of the PbI₂ nanocluster was triggered by continuous electron probe scanning. Insets are corresponding FFT patterns of each STEM-HAADF image, scale bar: 4 nm⁻¹. e, Corresponding out-of-plane strain ε_{yy} distributions of d generated by a GPA analysis, the intragrain strain generated from PbI₂ nano-cluster can be effectively relaxed by IGIA.

FIG. 2 Mechanistic insights into the intragrain impurity annihilation in PSCs. a, c, e, Atomic resolution STEM-HAADF images of intragrain PbI₂ impurity (marked by solid line region) and perovskite interfaces along perovskite (011̅), (011) and (001) plane, respectively. b, d, f, Modeled progression of phase-transformation from PbI₂ sheet structures with octahedra edge-sharing connectivity to the perovskite structures with octahedra corner-sharing connectivity by intercalation of FA/Cs and I originated from external energy stimulus in different PbI₂-perovskite interfaces in accordance with a, c, e, respectively. g, Calculated relative energy difference between the initial interface with higher proportions of PbI₂ sheet, intermediate structure with intercalation of FA/Cs and I, and final transition from PbI₂ sheet to perovskite structures for IGIA phase transformation at different interfaces. The intercalations of FA/Cs and I are highlighted by the diamond and circle.

FIG. 3 Calculated electronic and defect properties of the three interfaces formed by intragrain PbI₂ impurity and perovskite phase. a-c, The charge density corresponding to the VBM and CBM, the total DOS of the PbI₂-perovskite interfaces along perovskite (011̅), (011) and (001) plane correlated to atomic resolution STEM-HAADF images, respectively. The cyan, black, and purple spheres denote FA/Cs, Pb, and I atoms, respectively, and the shaded areas denote the computed charge density. d-f, Point defects of perovskites including vacancies, interstitials and anti-sites. Considering the progression of the structural transition, I, Pb, Cs/FA interstitials and I vacancies are focused in this study. The charge density (shaded area) of the shoulder peak near the band edges and total DOS for PbI₂-perovskite interfaces corresponds to a-c with one I interstitials (per supercell), respectively. The I interstitials per supercell is highlighted by the dashed circle.

FIG. 4 Leveraging intragrain impurity annihilation to improve perovskite solar cells. a, Schematic illustration of using a scanning laser probe for in-situ IGIA for PSCs; b, High-magnification STEM-HAADF images of the intragrain microstructure before and after IGIA for the same grain region; solid line and dashed line regions represent PbI₂ and non-PbI₂ intermediate phases that exist in the neatly synthesized perovskite film. c, Current-voltage (J-V) curves, and d IPCE spectra of PSCs before and after laser-induced IGIA; e, J-V curve of perovskite solar module with active area of 14 cm² with optimal laser treatment. f, Stability tests results for PSCs with different laser treatment conditions. The 2nd plot is referred to the device without IGIA. The 3rd plot is referred to the device with IGIA only at the film fabrication stage. The 1st plot is referred to the device with additional laser treatments during the device storage time. The laser icon illustrates the time slots the additional laser treatments are performed.

FIG. 5 Workflow of the sample preparation for our in situ STEM study. (i) The device sample lamella was first fabricated using FIB, (ii) then a 10 nm amorphous carbon coating was deposited from both sides, and finally, (iii) the sample lamella was wholly wrapped and stabilized.

FIG. 6 STEM-EDS mapping and atomic structure of the orthorhombic perovskite grain. a, STEM-EDS mapping of the FIB-fabricated PSC device cross-sectional specimen. b, Atomic resolution STEM-HAADF image of the orthorhombic perovskite FA_{0.5}Cs_{0.5}PbI₃ grain projected along [100]ₒ direction. c, Atomic model of the orthorhombic perovskite (space group Pnma) viewed from [100]ₒ direction, resolved according to the STEM-HAADF observation.

FIG. 7 The effect of annealing time on the distribution of perovskite intragrain impurity nanoclusters. a, High-resolution cross-sectional STEM-HAADF image of the FA_{0.5}Cs_{0.5}PbI₃ film prepared by the annealing condition (140° C., 60 min), showing a very low densities of intragrain impurities, respectively. b, High-resolution cross-sectional STEM-HAADF image of the FA_{0.5}Cs_{0.5}PbI₃ film prepared by the annealing condition (140° C., 90 min), showing a high density of intragrain impurities.

FIG. 8 The effect of short annealing time on the distribution of perovskite intragrain impurity nanoclusters. a, b, High-resolution cross-sectional STEM-HAADF image of the FA_{0.5}Cs_{0.5}PbI₃ film prepared by the annealing condition (140° C., 30 min), showing a high density of intragrain impurities.

FIG. 9 The influence of reservation to perovskite intragrain impurities. a, b, High-resolution STEM-HAADF images of the cross-sectional FA_{0.5}Cs_{0.5}PbI₃ specimen observed immediately after the FIB processing, taken from the perovskite grain surface and inner regions, respectively. The density of intragrain impurities at this stage is low. c, d, High-resolution STEM-HAADF images of the cross-sectional FA_{0.5}Cs_{0.5}PbI₃ specimen after 2-day storage in the vacuum package. A significant amount of intragrain impurities can be observed at this stage.

FIG. 10 Atomic structure of the PbI₂ nanocluster in perovskite grain. a, Atomic resolution STEM-HAADF image of the orthorhombic perdovskite FA_{0.5}Cs_{0.5}PbI₃ grain containing a PbI₂ nanocluster projected along [110]ₒ direction. Inset is the enlarged image of the selected region, showing the detailed PbI₂ atomic structure that is consistent with the standard structure model. b, Atomic model of PbI₂ viewed from [110]ₒ direction.

FIG. 11 Possible atomic structure of the non-PbI₂ intermediate phase nanocluster in the perovskite grain. a, Atomic-resolution STEM-HAADF image of an orthorhombic perovskite FA_{0.5}Cs_{0.5}PbI₃ grain (projected along [100]ₒ direction) contains a possibly non-PbI₂ intermediate phase nanocluster. Inset is the enlarged image of the selected region, showing the detailed atomic structure. b, Possible atomic model of the non-PbI₂ intermediate phase resolved according to the STEM-HAADF image.

FIG. 12 Intragrain impurities in different perovskite systems. a, Low-magnification STEM-HAADF image of the cross-sectional FA_{0.5}Cs_{0.5}PbI₃ PSC device specimen, showing no obvious FIB-caused damage in the perovskite layer. b, High-resolution STEM-HAADF image show a small amount of intragrain PbI₂ impurity nanoclusters. c, Low-magnification STEM-HAADF image of cross-sectional MA_{0.5}Cs_{0.5}PbI₃ device specimen, indicating no obvious FIB-caused damage in the perovskite layer. d, High-resolution STEM-HAADF image shows the existence of a similar distribution of intragrain PbI₂ nanoclusters.

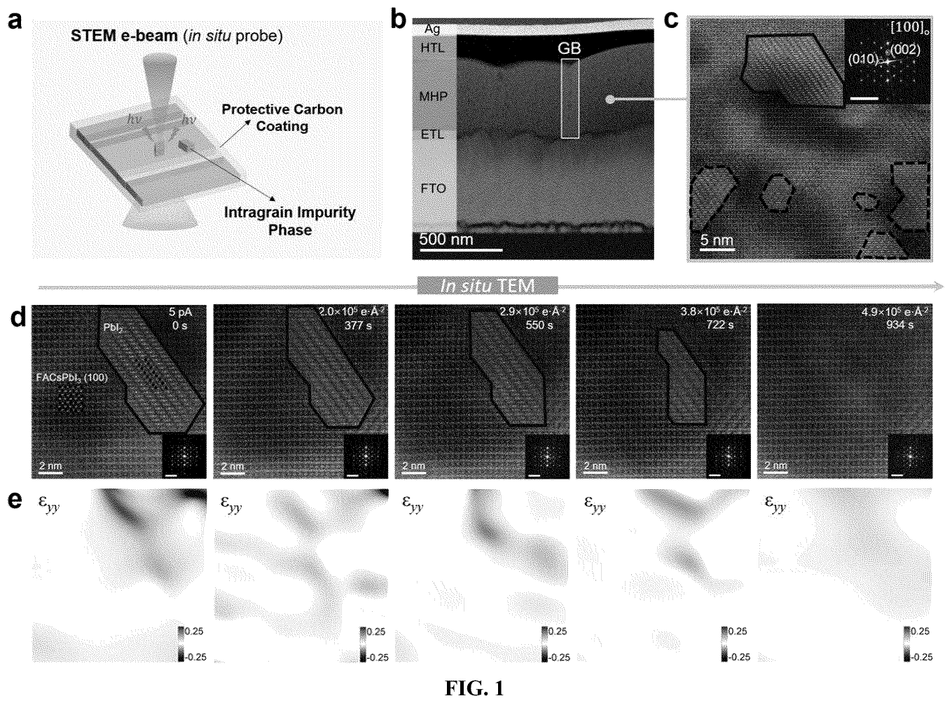

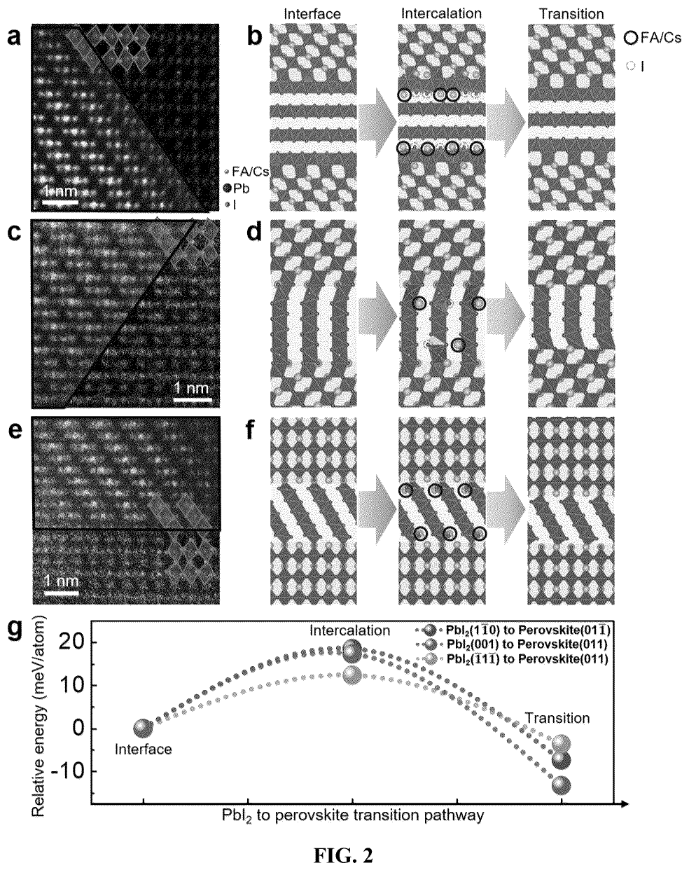

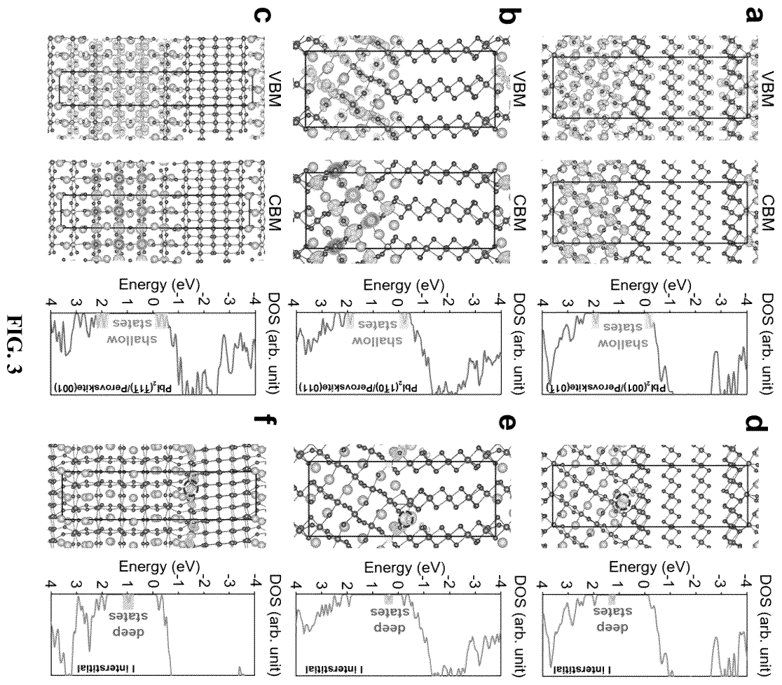

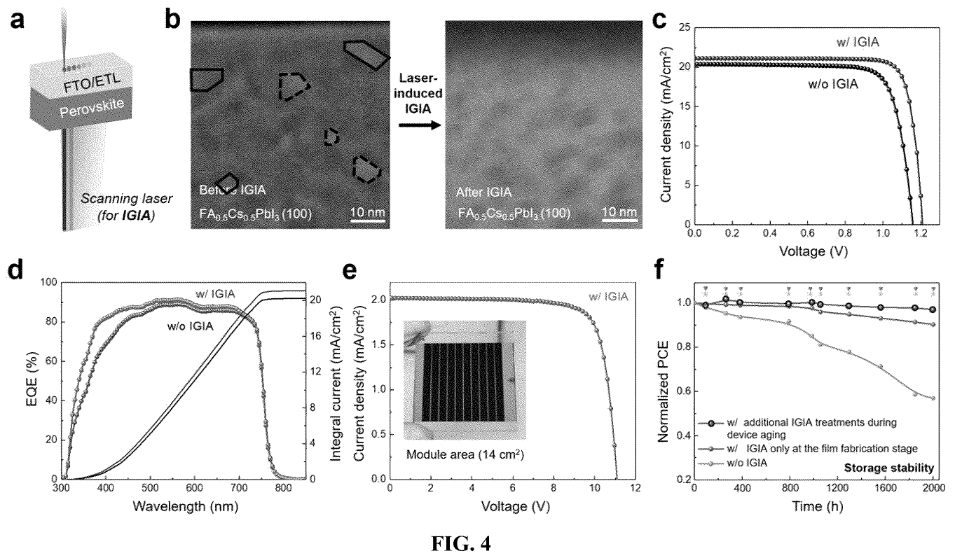

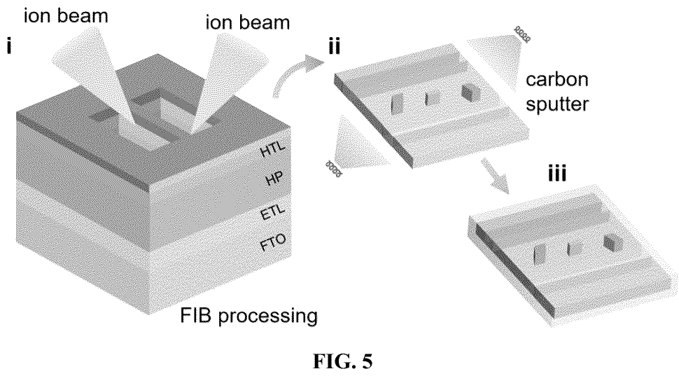

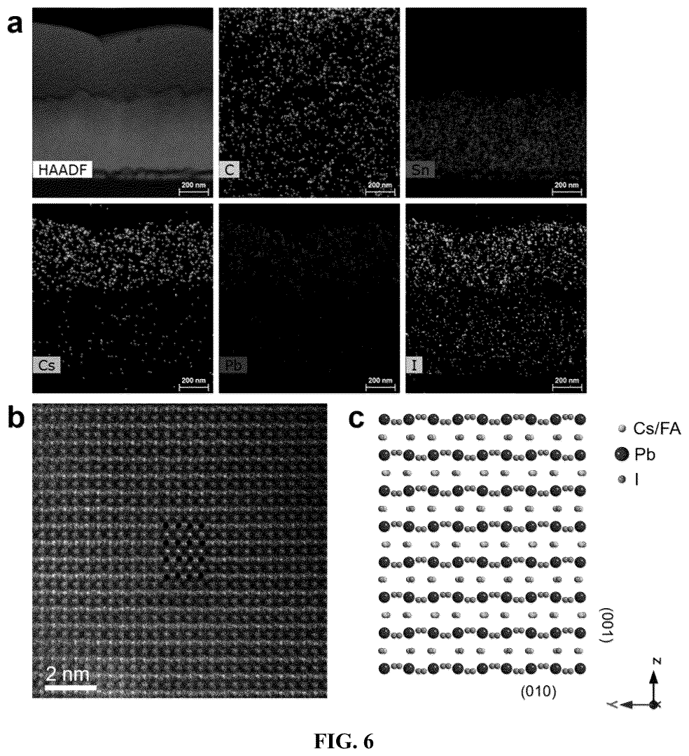

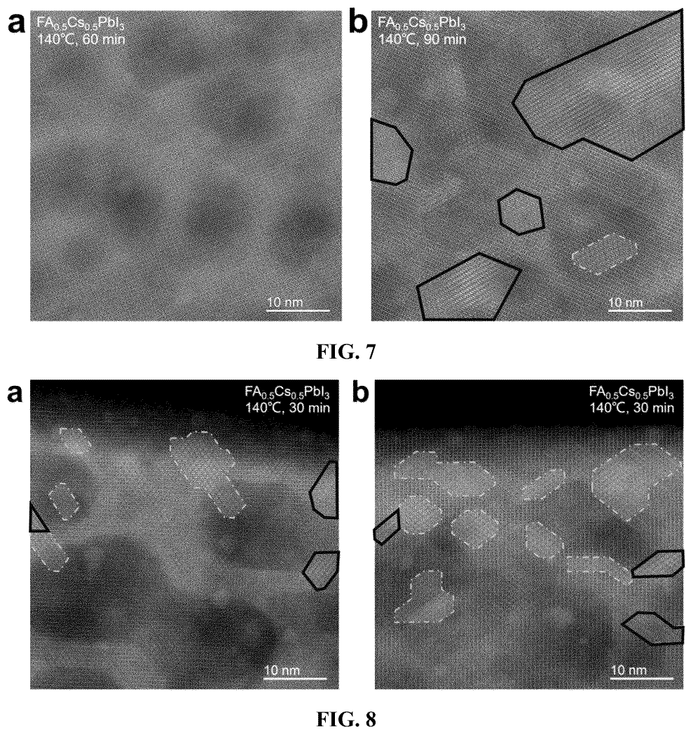

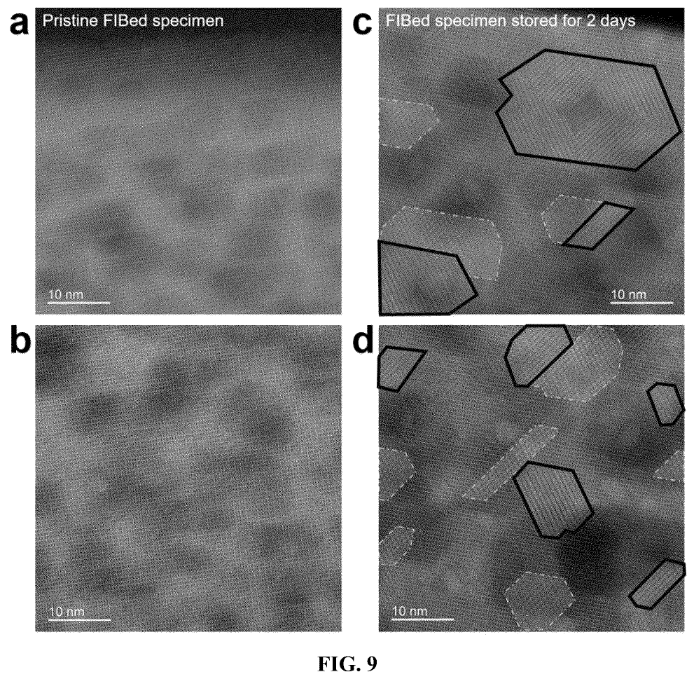

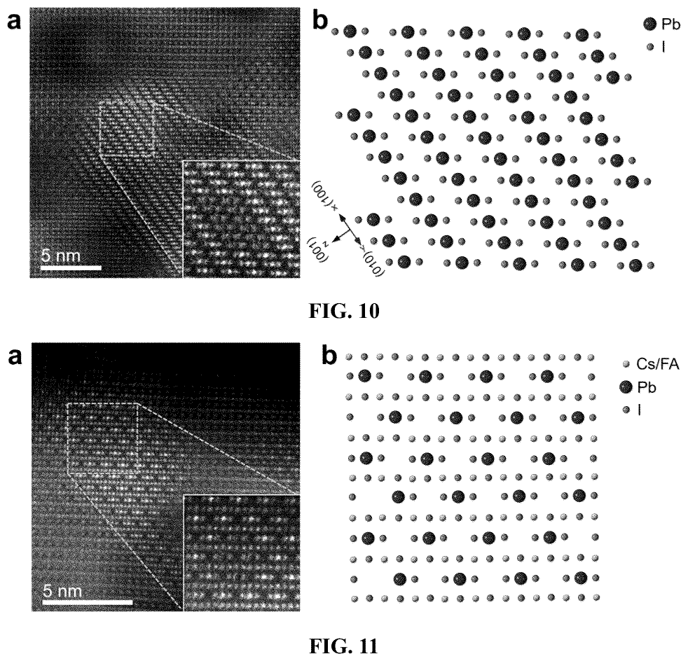

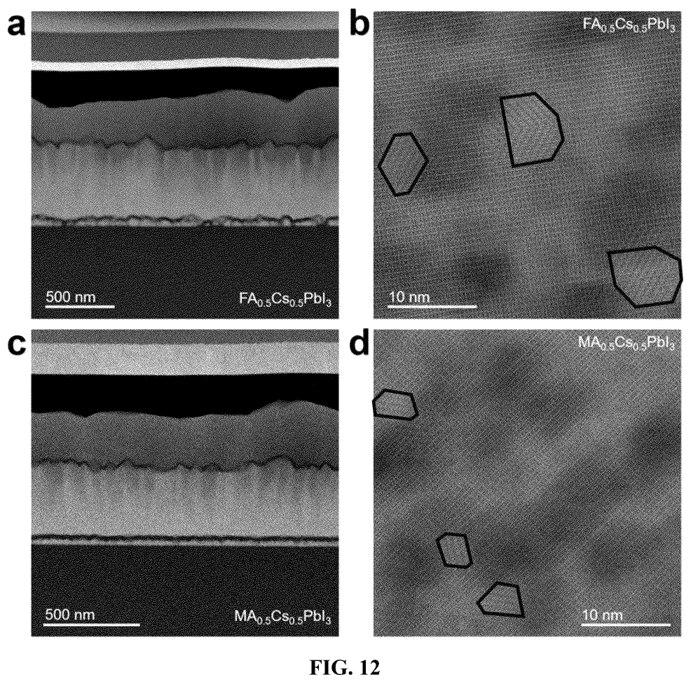

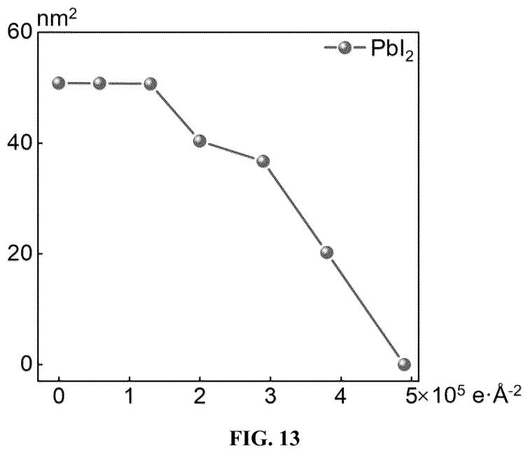

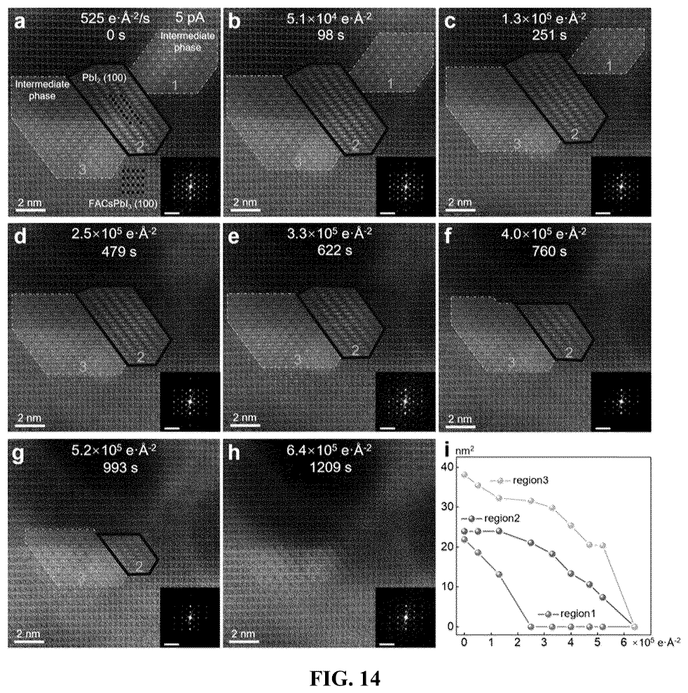

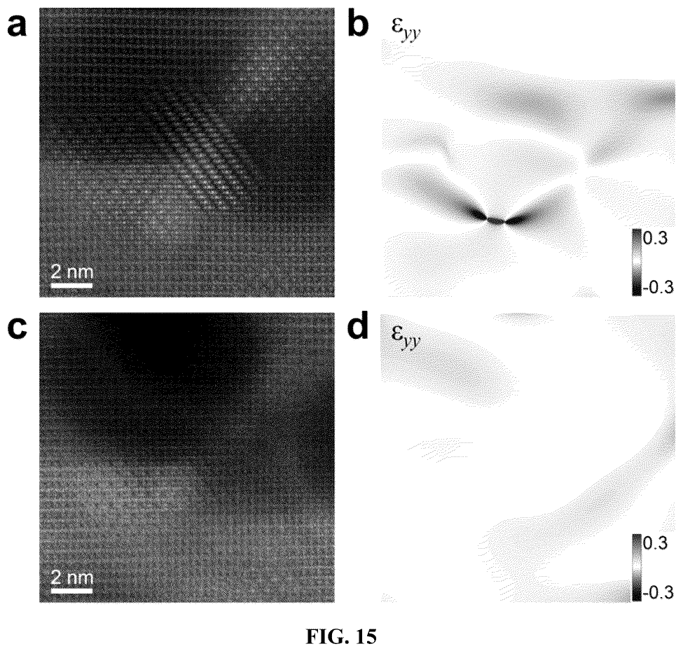

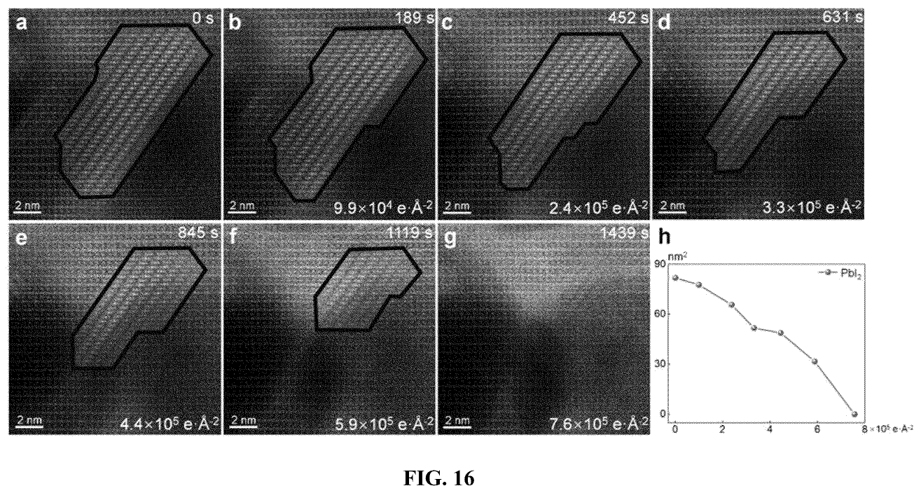

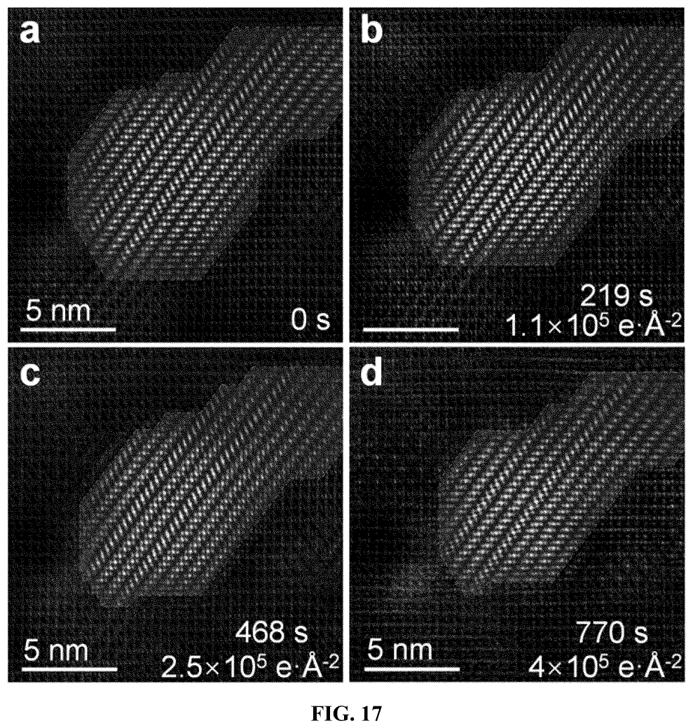

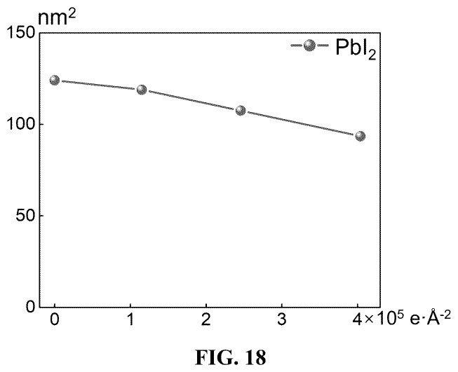

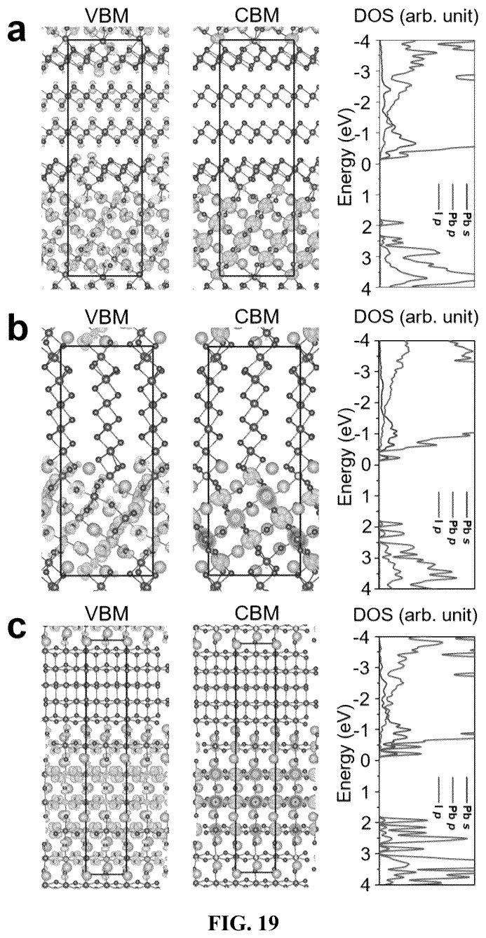

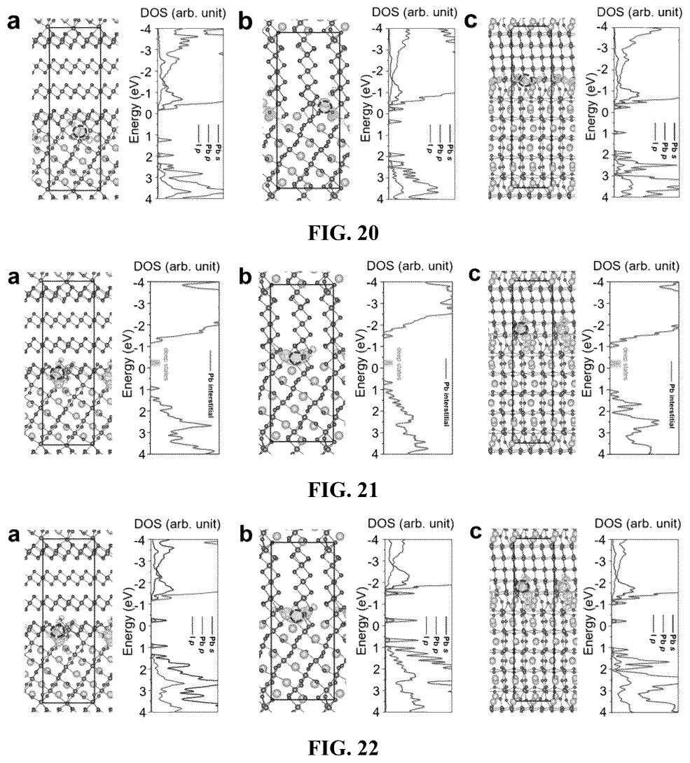

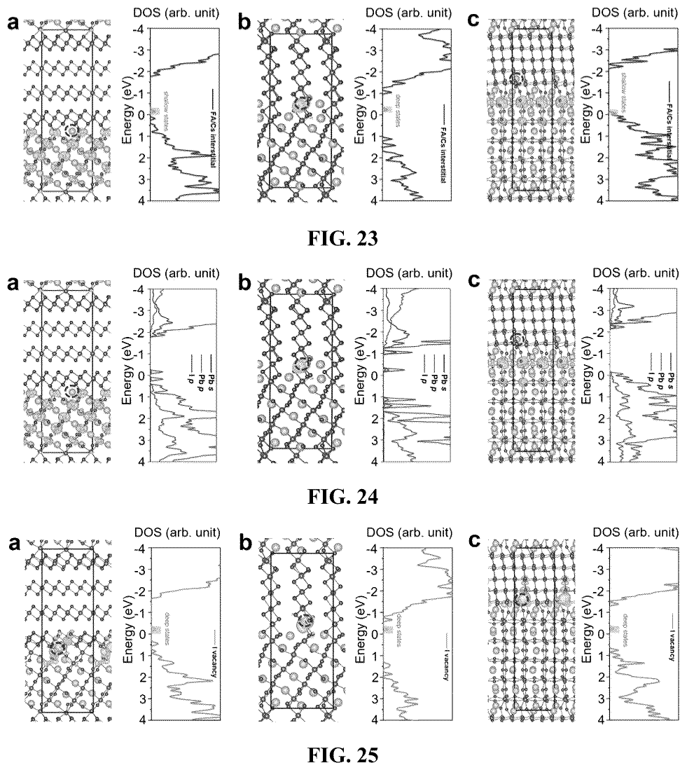

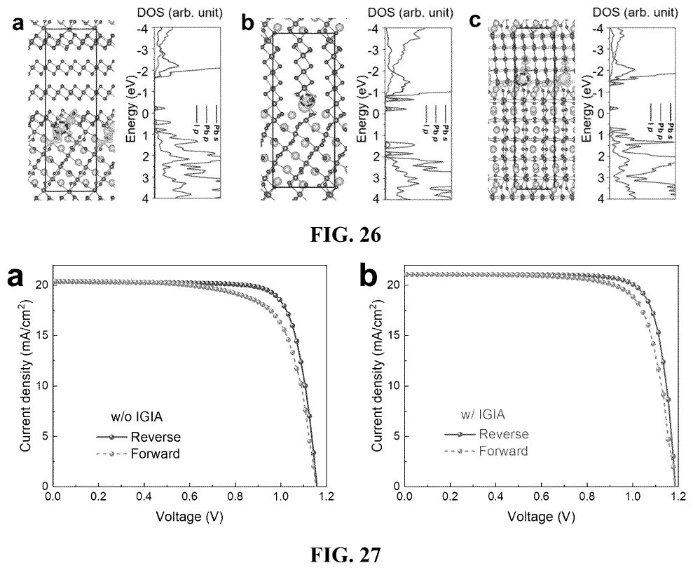

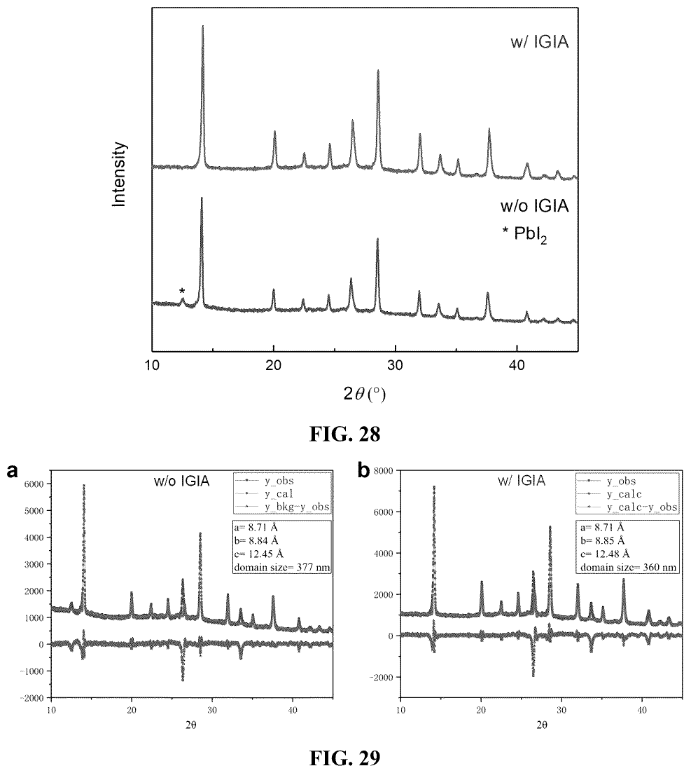

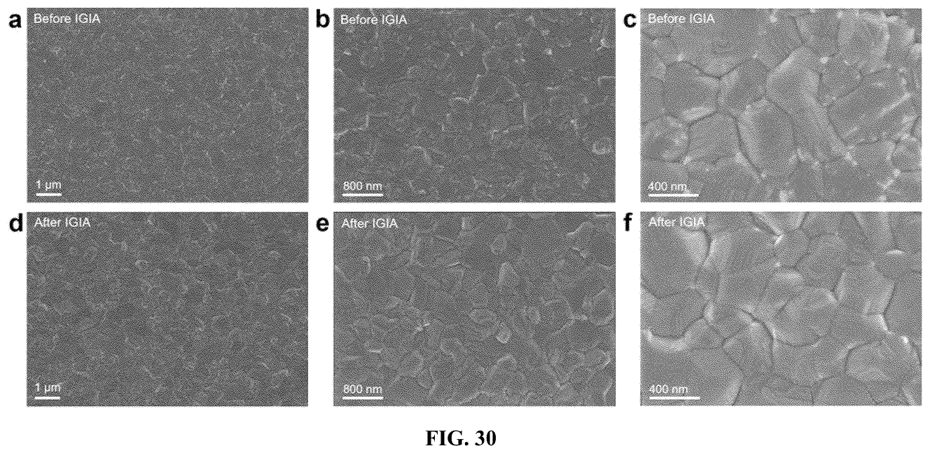

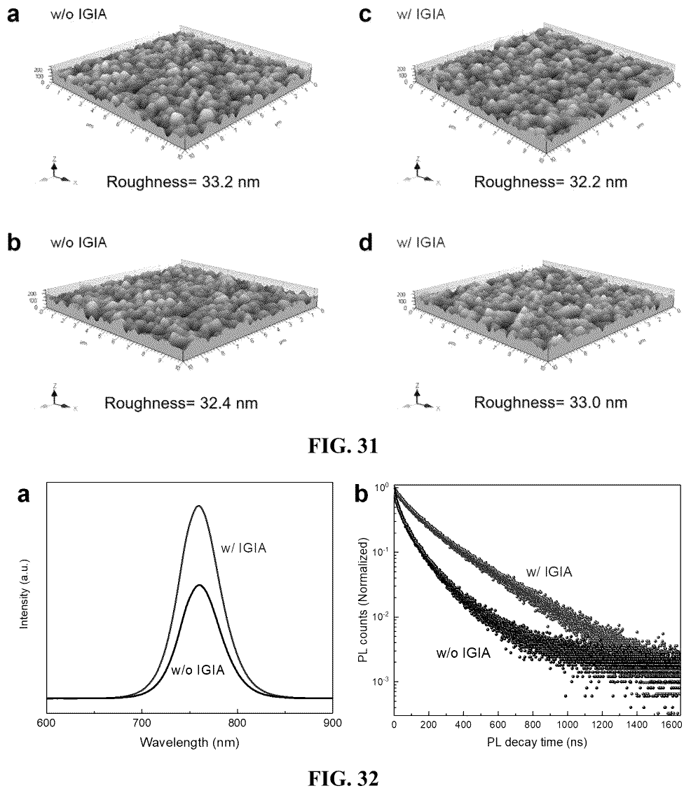

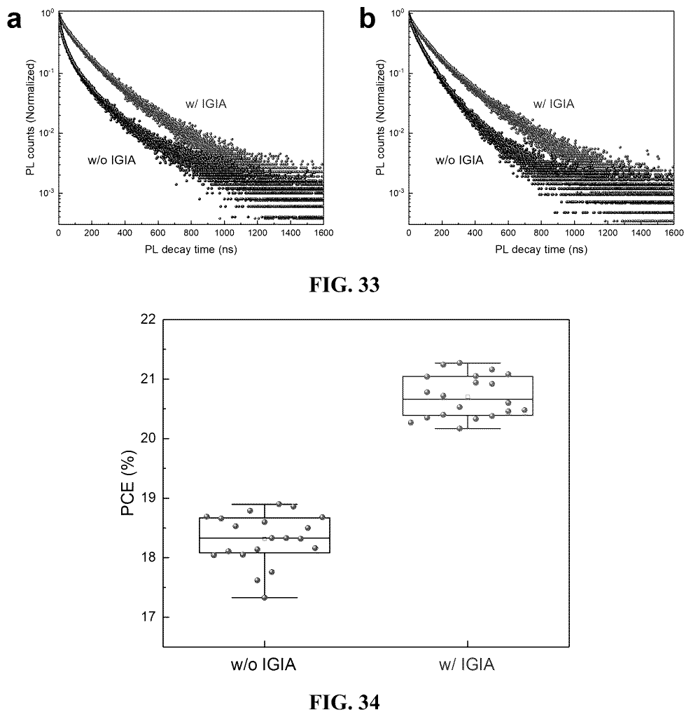

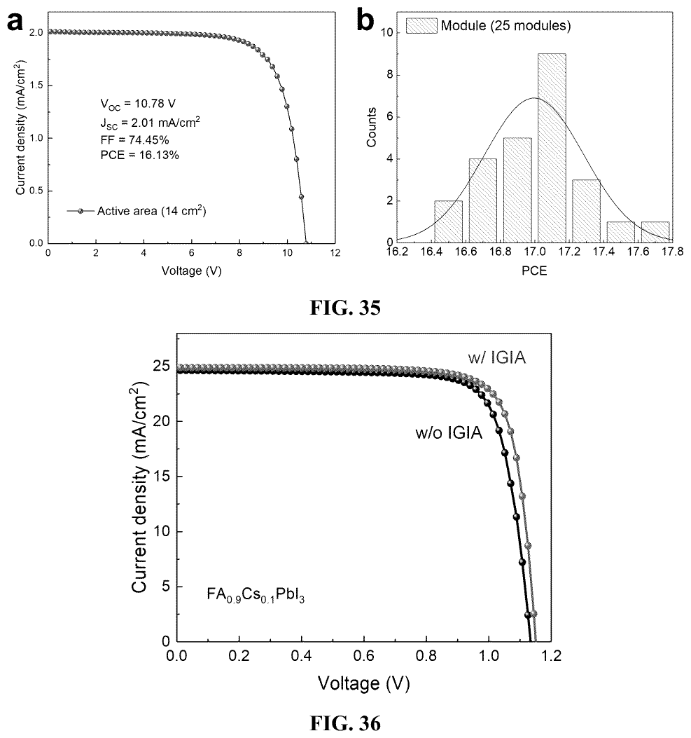

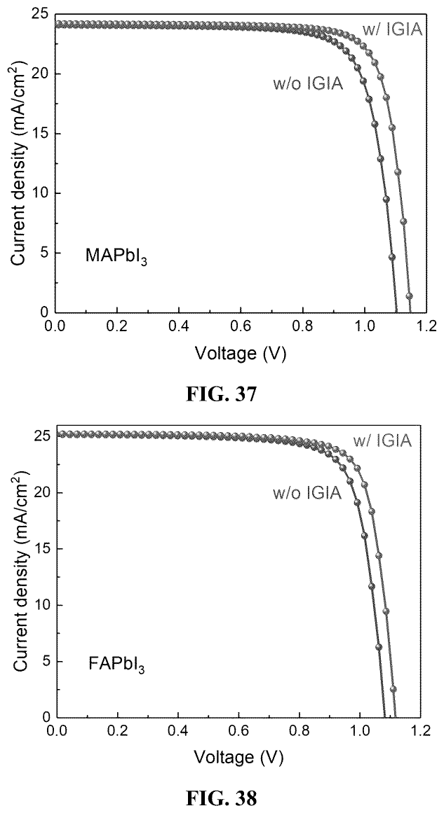

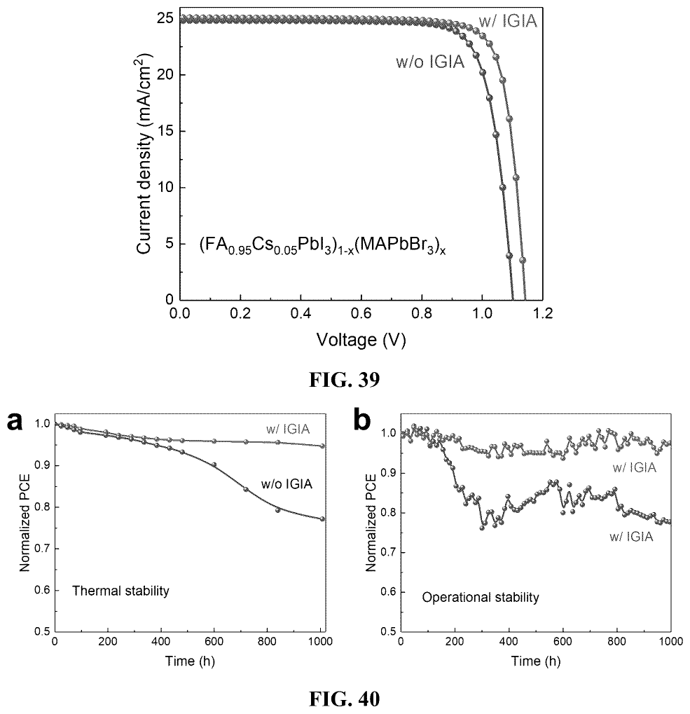

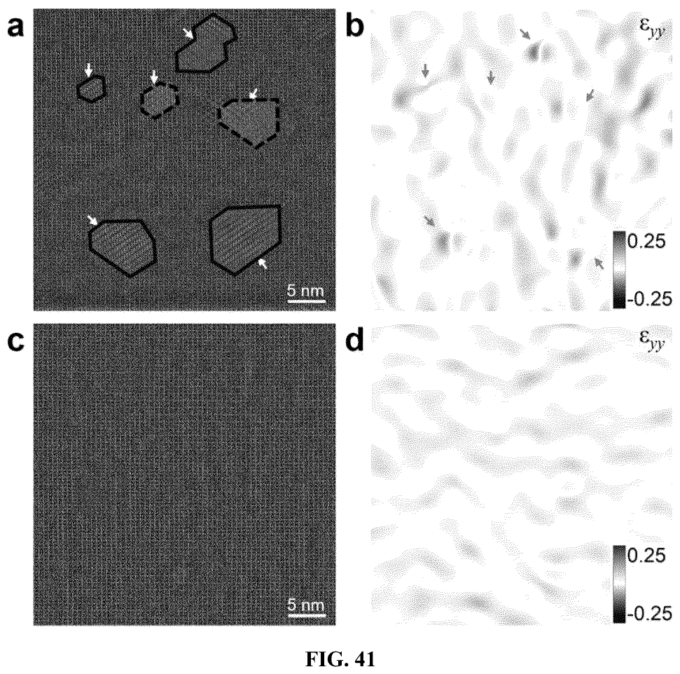

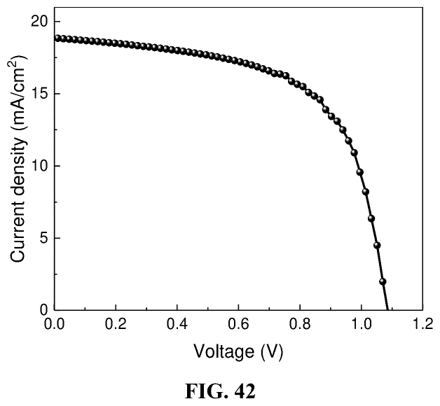

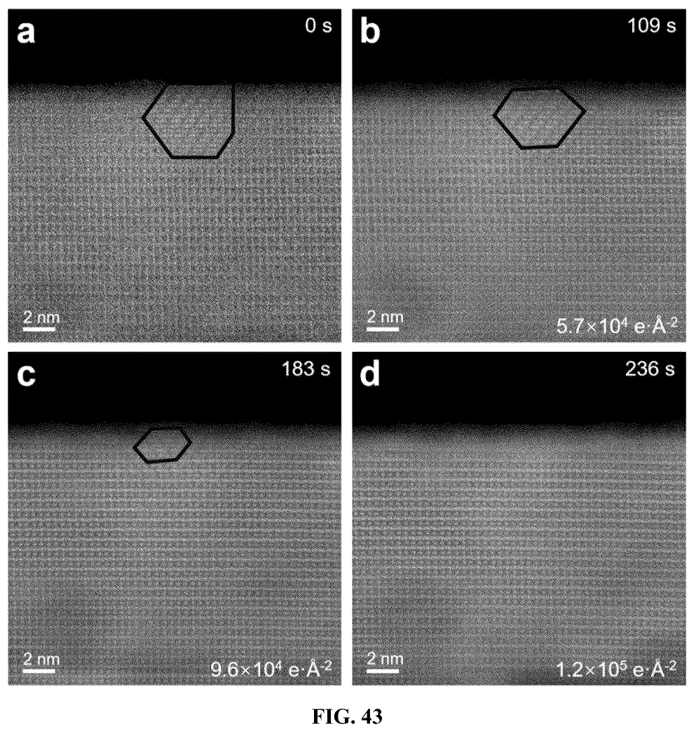

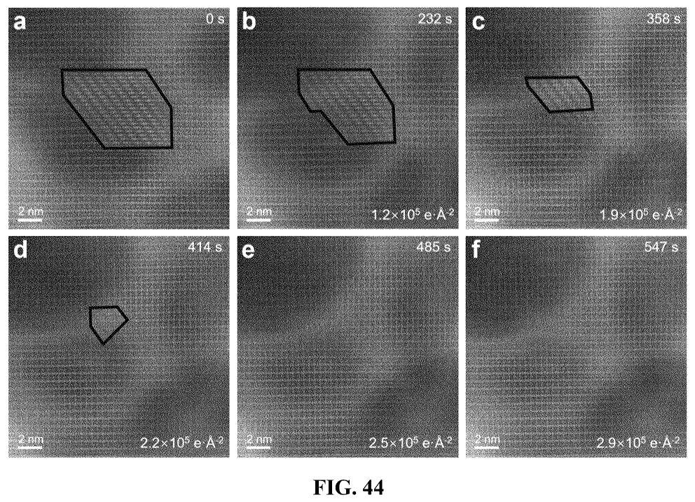

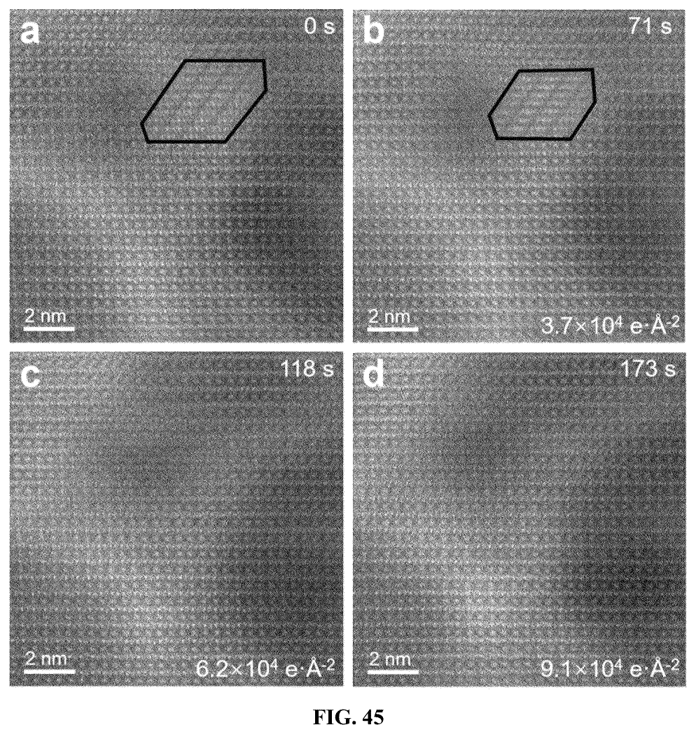

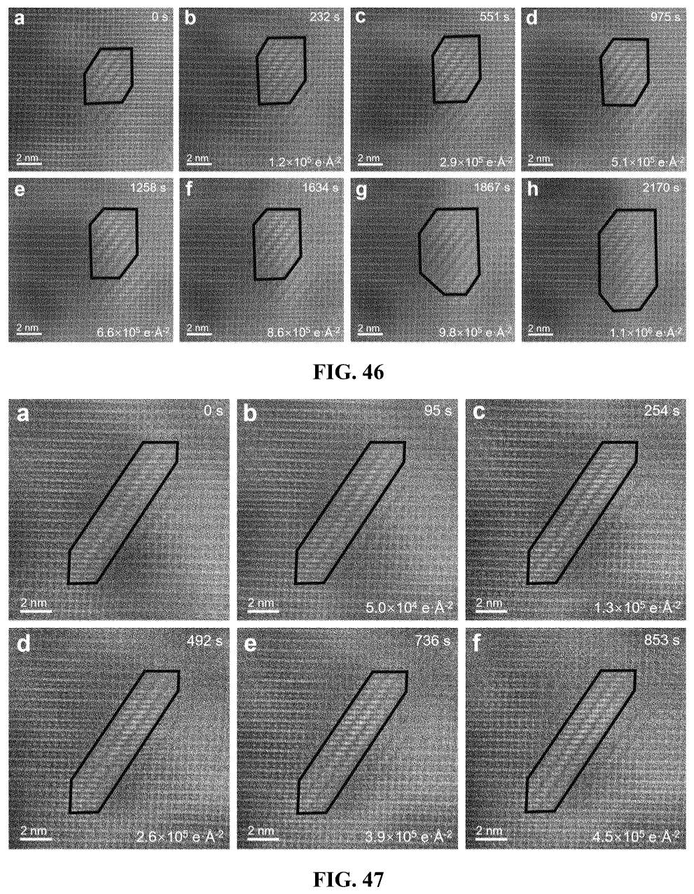

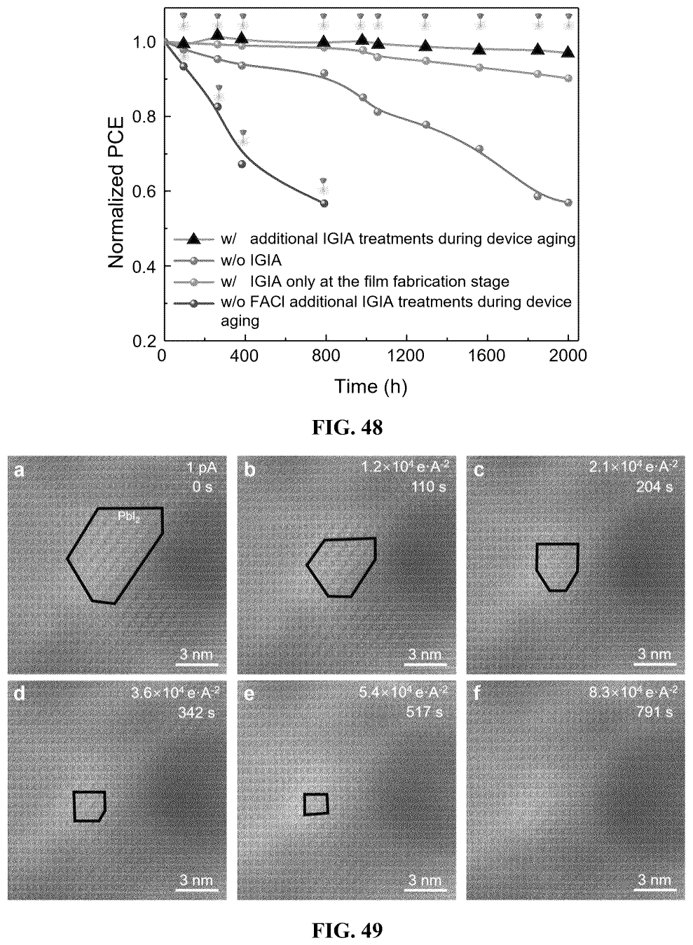

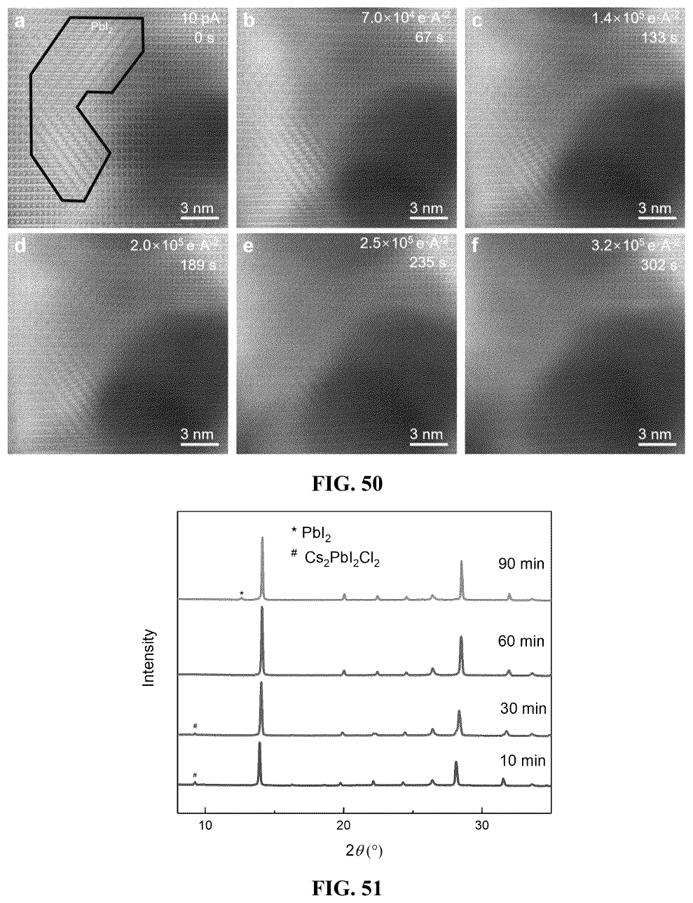

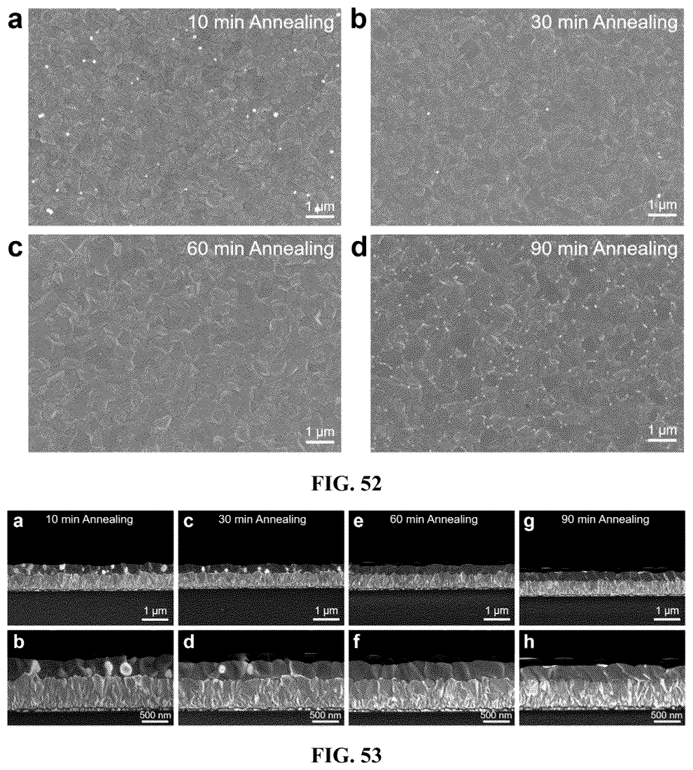

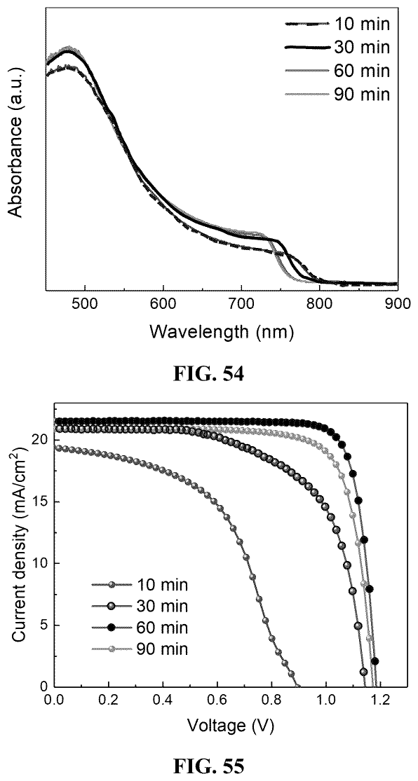

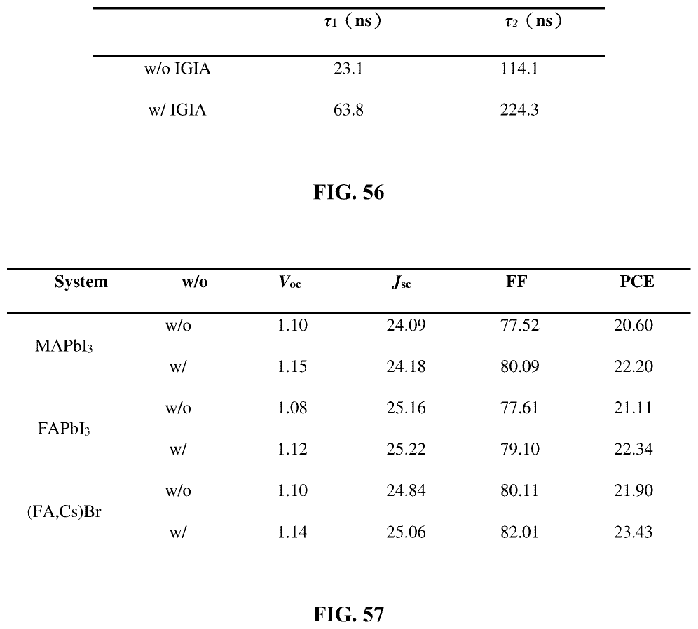

FIG. 13 The size shrinkage of the PbI₂ nanocluster with respect to the accumulated electron dose in FIG. 1d.

FIG. 14 Atomic level in situ observation of mixed phase-healing process. a, Atomic resolution STEM-HAADF image of orthorhombic (FA,Cs)PbI₃ nano-region projected along [100]ₒ direction contains both PbI₂ (marked by solid line region and dashed lines) and non-PbI₂ impurity phase (marked by dashed line regions and dashed lines) nanoclusters. b-h, The in situ phase-healing process with continuous electron probe scanning. Insets are corresponding FFT patterns of each STEM image. Scale bar: 4 l/nm. i, The area shrinkage of regions 1-3 with respect to the accumulated electron dose.

FIG. 15 Perovskite intragrain strain relaxation by phase-healing. a, Atomic-resolution STEM-HAADF image of a perovskite grain contains both PbI₂ nanocluster and non-PbI₂ impurity phase, similar to that in FIG. 10a. b, GPA mapping of out-of-plane strain (ε_{yy}) distribution in a, showing the PbI₂ nanocluster and non-PbI₂ impurity phase can induce uneven intragrain strain distribution. c, STEM-HAADF image after IGIA, similar to that in FIG. 10h. d, GPA mapping of out-of-plane strain (yy) distribution in c, showing the intragrain strain is relaxed.

FIG. 16 Transformation of a medium-size PbI₂ impurity nanocluster to perovskite. a, Atomic resolution STEM-HAADF image of orthorhombic FA_{0.5}Cs_{0.5}PbI₃ nano-region projected along [100]ₒ direction contains a relatively large PbI₂ nanocluster with a projected size of ˜80 nm² (marked with the solid line). b-g, The in-situ recorded transformation process of the PbI₂ nanocluster under a continuous electron probe scanning. h, The size shrinkage of the PbI₂ nanocluster with respect to the accumulated electron dose.

FIG. 17 The beginning stage of the transformation from a large-size PbI₂ nanocluster to perovskite. a, Atomic resolution STEM-HAADF image of orthorhombic FA_{0.5}Cs_{0.5}PbI₃ nano-region projected along [100]ₒ direction contains a much larger PbI₂ nanocluster with a size exceeding 120 nm² (marked by the dashed line). b-d, The in situ recorded transformation process of the PbI₂ nanocluster with continuous electron probe scanning.

FIG. 18 The size shrinkage of the PbI₂ impurity nanocluster with respect to the accumulated electron dose in FIG. 16.

FIG. 19 Partial DOS of the three intragrain PbI₂-perovskite interfaces. a-c, Charge density (shaded area) of the shoulder peak near the band edges and partial DOS for Pb s, p orbitals and I p orbitals for PbI₂-perovskite interfaces on the perovskite (011̅), (011) and (001) plane, respectively.

FIG. 20 Partial DOS of the three intragrain PbI₂-perovskite interfaces with I interstitial. a-c, Charge density (shaded area) of the shoulder peak near the band edges and partial DOS for Pb s, p orbitals and I p orbitals for PbI₂-perovskite interfaces corresponds to FIG. 3d-f with one I interstitial (per supercell), respectively.

FIG. 21 Electronic structures of the three intragrain PbI₂-perovskite interfaces with Pb interstitial. a-c, Charge density (shaded area) of the shoulder peak near the band edges and total DOS for PbI₂-perovskite interfaces along perovskite (011̅), (011) and (001) plane with one Pb interstitial (per supercell), respectively.

FIG. 22 Partial DOS of the three intragrain PbI₂-perovskite interfaces with Pb interstitial. a-c, Charge density (shaded area) of the shoulder peak near the band edges and partial DOS for Pb s, p orbitals and I p orbitals for PbI₂-perovskite interfaces corresponds to Supplementary FIG. 16 with one Pb interstitial (per supercell), respectively.

FIG. 23 Electronic structures of the three intragrain PbI₂-perovskite interfaces with FA/Cs interstitial. a-c, Charge density (shaded area) of the shoulder peak near the band edges and total DOS for PbI₂-perovskite interfaces along perovskite (011̅), (011) and (001) plane with one FA/Cs interstitial (per supercell), respectively.

FIG. 24 Partial DOS of the three intragrain PbI₂-perovskite interfaces with FA/Cs interstitial. a-c, Charge density (shaded area) of the shoulder peak near the band edges and partial DOS for Pb s, p orbitals and I p orbitals for PbI₂-perovskite interfaces corresponds to FIG. 22 with one FA/Cs interstitial (per supercell), respectively.

FIG. 25 Electronic structures of the three intragrain PbI₂-perovskite interfaces with I vacancy. a-c, Charge density (shaded area) of the shoulder peak near the band edges and total DOS for PbI₂-perovskite interfaces along perovskite (011̅), (011) and (001) plane with one I vacancy (per supercell), respectively.

FIG. 26 Partial DOS of the three intragrain PbI₂-perovskite interfaces with I vacancy. a-c, Charge density (shaded area) of the shoulder peak near the band edges and partial DOS for Pb s, p orbitals and I p orbitals for PbI₂-perovskite interfaces corresponds to Supplementary FIG. 20 with one I vacancy (per supercell), respectively.

FIG. 27 J-V hysteresis of an FA-Cs PSC before and after laser-induced IGIA. a, J-V hysteresis of an FA-Cs PSC before laser-induced IGIA. b, J-V hysteresis of FA-Cs PSC after laser-induced IGIA.

FIG. 28 X-ray diffraction (XRD) patterns of FA_{0.5}Cs_{0.5}PbI₃ films before and after laser-induced IGIA.

FIG. 29 Refinement of XRD results presented in FIG. 27. a, The lattice parameters of FA_{0.5}Cs_{0.5}PbI₃ perovskite film before laser-induced IGIA are measured as a=8.71 Å, b=8.84 Å, and c=12.45 Å, and the crystalline domain size is estimated to be 377 nm from the XRD refinement. b, The lattice parameters of FA_{0.5}Cs_{0.5}PbI₃ perovskite film after laser treatment are measured as a=8.71 Å, b=8.85 Å, and c=12.48 Å, and the crystalline domain size is estimated to be 360 nm from the XRD refinement. XRD refinements were carried out using Rietveld method with the GSAS (General Structure Analysis System) software. Note that the reliability factors (R_{w}) for refinements of XRD results obtained from film samples before and after laser-induced IGIA were 9.006 and 11.020, respectively.

FIG. 30 SEM images of the surface morphology of FA-Cs perovskite film before and after laser-induced IGIA. a-c, Low-magnification and high-magnification SEM images of the FA_{0.5}Cs_{0.5}PbI₃ perovskite film before laser-induced IGIA, respectively. d-f, Low-magnification and high-magnification SEM images of the FA_{0.5}Cs_{0.5}PbI₃ perovskite film after laser-induced IGIA, indicating little change in perovskite morphology.

FIG. 31 AFM measurement of the FA-Cs perovskite film surface roughness before and after laser-induced IGIA. a, b, AFM images of FA_{0.5}Cs_{0.5}PbI₃ perovskite film surface before laser-induced IGIA. c, d, AFM images of FA_{0.5}Cs_{0.5}PbI₃ perovskite film surface after laser-induced IGIA. Only slight variations in roughness are observed amongst these films.

FIG. 32 Steady-state photoluminescence (PL) and Time-resolved photoluminescence (TRPL) measurement of the FA-Cs perovskite film before and after laser-induced IGIA. a, PL spectra and b, TRPL spectra of FA_{0.5}Cs_{0.5}PbI₃ films before and after laser-induced IGIA, respectively.

FIG. 33 Time-resolved photoluminescence (TRPL) measurement of the FA-Cs perovskite film before and after laser-induced IGIA. a, b, TRPL spectra of FA_{0.5}Cs_{0.5}PbI₃ films before and after laser-induced IGIA measured from two different sites spaced at a distance of more than 5 mm.

FIG. 34 PCE statistics of 20 individual devices before and after laser-induced IGIA.

FIG. 35 Current-voltage (J-V) curves and PCE of modules. a, J-V curve of a 14 cm₂ solar module before laser-induced IGIA. b, The PCE statistic of 25 modules after laser-induced IGIA.

FIG. 36 Current-voltage (J-V) curves of FA_{0.9}Cs_{0.1}PbI₃ PSCs before and after laser-induced intragrain phase-healing. The champion solar cell based on the target film displays a PCE of 22.87%, with open-circuit voltage (V_{OC}) of 1.15 V, short-circuit current density (J_{SC}) of 24.88 mA/cm², fill factor (FF) of 79.94%, demonstrating an obvious improvement, as compared with the 21.93% PCE of the control device (V_{OC}: 1.13 V; J_{SC}: 24.63 mA/cm²; FF: 78.54%).

FIG. 37 Current-voltage (J-V) curves of MAPbI₃ PSCs before and after laser-induced IGIA.

FIG. 38 Current-voltage (J-V) curves of FAPbI₃ PSCs before and after laser-induced IGIA.

FIG. 39 Current-voltage (J-V) curves of (FA_{0.95}Cs_{0.05}PbI₃)₁₋ₓ(MAPbBr₃)ₓ PSCs before and after laser-induced IGIA.

FIG. 40 Thermal stability and operational stability tests of FA-Cs PSCs before and after laser-induced IGIA. a, Thermal stability of FA-Cs PSC with and without laser-induced IGIA tested at 85° C. for 1000 h. b, Operational stability of FA-Cs PSC with and without laser-induced IGIA tested under one-sun illumination for 1000 h.

FIG. 41 Perovskite intragrain strain relaxation coupled with laser-induced IGIA. a, Atomic-resolution STEM-HAADF image of pristine perovskite grain in as-fabricated PSC sample contains both PbI₂ and non-PbI₂ impurity nanoclusters. b, GPA mapping of out-of-plane strain (ε_{yy}) distribution in a, indicating the PbI₂ nanocluster and non-PbI₂ impurity phase induced uneven intragrain strain as marked by arrows. c, STEM-HAADF image of PSC sample after laser-induced IGIA with a reduced impurity density. d, GPA mapping of out-of-plane strain (ε_{yy}) distribution in c, showing that intragrain strain is effectively relaxed.

FIG. 42 Current-voltage (J-V) curves of FA_{0.5}Cs_{0.5}PbI₃ PSC after laser treatment for 10 min (PCE: 12.5%; V_{OC}: 1.08 V; J_{SC}: 18.85 mA/cm2; FF: 61.40%).

FIG. 43 In situ STEM observation of intragrain impurity annihilation in MA-Cs perovskite. a, A PbI₂ nanocluster locates near the surface of MA_{0.5}Cs_{0.5}PbI₃ perovskite grain. b-d, The shrinkage and annihilation of this PbI₂ nanocluster under electron probe scanning.

FIG. 44 In situ STEM observation of intragrain impurity annihilation in MA-Cs perovskite. a, A PbI₂ nanocluster locates in the inner region of MA_{0.5}Cs_{0.5}PbI₃ perovskite grain. b-d, The shrinkage and annihilation (e, f) of this PbI₂ nanocluster under electron probe scanning.

FIG. 45 In situ STEM observation of intragrain impurity annihilation in over-annealed FA-Cs perovskite. a, A PbI₂ nanocluster exists in FA_{0.5}Cs_{0.5}PbI₃ perovskite grain prepared by 140° C., 90 min annealing. b-d, The shrinkage and annihilation of this PbI₂ nanocluster under electron probe scanning.

FIG. 46 In situ STEM observation of intragrain impurity evolution in FA-Cs perovskite prepared without FACl incorporation. a, A PbI₂ nanocluster exists in FA_{0.5}Cs_{0.5}PbI₃ perovskite grain prepared without FACl incorporation. b-h, The slight expansion of this PbI₂ nanocluster under electron probe scanning.

FIG. 47 In situ STEM observation of intragrain impurity evolution in MA-Cs perovskite prepared without MACI incorporation. a, A PbI₂ nanocluster exists in MA_{0.5}Cs_{0.5}PbI₃ perovskite grain prepared without MACI incorporation. b-h, The size of this PbI₂ nanocluster exhibits little change under electron probe scanning.

FIG. 48 Stability test of FA-Cs PSCs with different laser treatment and synthesis conditions. The different plots are same with FIG. 4f. The black curve represents the result of PSC device prepared from FA_{0.5}Cs_{0.5}PbI₃ perovskite prepared without FACl incorporation, and the laser treatment has no effect compared with the normally prepared devices.

FIG. 49 In situ STEM observation of intragrain impurity annihilation under smaller electron beam current. a, A PbI₂ nanocluster exists in FA_{0.5}Cs_{0.5}PbI₃ perovskite grain. b-f, The shrinkage and annihilation of this PbI₂ nanocluster under 1 pA electron probe scanning.

FIG. 50 In situ STEM observation of intragrain impurity evolution under larger electron beam current. a, A PbI₂ nanocluster exists in FA_{0.5}Cs_{0.5}PbI₃ perovskite grain. b-f, The perovskite structure gradually collapse under 10 pA electron probe scanning.

FIG. 51 XRD patterns of FA_{0.5}Cs_{0.5}PbI₃ films prepared with different annealing times.

FIG. 52 Top-view SEM images of FA_{0.5}Cs_{0.5}PbI₃ perovskite films with different annealing times. a-d, Top-view SEM images of perovskite films annealed for 10 min, 30 min, 60 min and 90 min, respectively. Some large bright-contrast clusters exist in the 10 min (a) and 30 min (b) cases. For the 90 min case (d), numerous bright-contrast dots appear onto the film surface.

FIG. 53 Cross-sectional SEM images of FA_{0.5}Cs_{0.5}PbI₃ perovskite films made with different annealing times. a-h, Cross-sectional SEM images of perovskite films that are annealed for 10 min (a, b), 30 min (c, d), 60 min (e, f) and 90 min (g, h), respectively. For the 10 min (a, b) and 30 min (c, d) cases, some large bright-contrast clusters exist in the film bulk. For the 90 min case (g, h), only some bright-contrast dots appear onto the film surface.

FIG. 54 UV-vis spectra of FA_{0.5}Cs_{0.5}PbI₃ perovskite films made with different annealing times.

FIG. 55 Current-voltage (J-V) curves of PSCs fabricated using FA_{0.5}Cs_{0.5}PbI₃ perovskite films made with different annealing times.

FIG. 56 Table showing calculated carrier lifetime values.

FIG. 57 Table showing calculated carrier lifetime values.

### DETAILED DESCRIPTION

### Definitions

Throughout the present disclosure, unless the context requires otherwise, the word “comprise” or variations such as “comprises” or “comprising”, will be understood to imply the inclusion of a stated integer or group of integers but not the exclusion of any other integer or group of integers. It is also noted that in this disclosure and particularly in the claims and/or paragraphs, terms such as “comprises”, “comprised”, “comprising” and the like can have the meaning attributed to it in U.S. Patent law; e.g., they can mean “includes”, “included”, “including”, and the like; and that terms such as “consisting essentially of” and “consists essentially of” have the meaning ascribed to them in U.S. Patent law, e.g., they allow for elements not explicitly recited, but exclude elements that are found in the prior art or that affect a basic or novel characteristic of the present invention.

Furthermore, throughout the present disclosure and claims, unless the context requires otherwise, the words “include”, “comprise” or variations such as “includes”, “including” “comprises” or “comprising”, will be understood to imply the inclusion of a stated integer or group of integers, but not the exclusion of any other integer or group of integers.

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a ±10%, ±7%, ±5%, ±3%, ±1%, or ±0% variation from the nominal value unless otherwise indicated or inferred.

The present disclosure provides a method of reducing intragrain impurities in a perovskite, the method comprising: irradiating the perovskite with an energy beam selected from the group consisting of a laser beam and an electron beam thereby reducing the intragrain impurities in the perovskite.

In certain embodiments, the intragrain impurities comprise (M²⁺)(X⁻)₂ and (A⁻)(X³¹ ), and the perovskite comprises a Formula (A⁺) (M²⁺)(X⁻)₃, wherein M²⁺ comprises Pb²⁺, Sn²⁺, Ge²⁺, or a mixture thereof; X⁻ comprises F⁻, Cl⁻, Br⁻, I⁻, or a mixture thereof, and A⁺ comprises Cs⁺, Rb⁺, CH₃NH₃⁺, CH₃CH₂NH₃⁺, H(C═NH₂)NH₂⁺, Me(C═NH₂)NH₂⁺, or a mixture thereof. In certain embodiments, irradiating with the energy beam results in conversion of at least a portion of (M²⁺)(X⁻)₂ and (A⁺)(X⁻) to perovskite.

In certain embodiments, M²⁺ comprises Pb²⁺.

In certain embodiments, X⁻ is Br⁻ or I⁻. In certain embodiments, X⁻ comprises I⁻.

In certain embodiments, A⁺ comprises Cs⁺, CH₃NH₃⁺, H(C═NH₂)NH₂⁺, or a mixture thereof.

In certain embodiments, (M²⁺)(X⁻)₂ comprises PbI₂.

In certain embodiments, (A⁺)(X⁻) comprises CsI, CH₃NH₃I, H(C═NH₂)NH₂I, or a mixture thereof.

In certain embodiments, the perovskite bas a Formula (A⁺)_{y}(A′⁺)_{1-y}(M²⁺)(X⁻)₃, wherein M²⁺ comprises Pb²⁺, Sn²⁺, Ge²⁺, or a mixture thereof; X⁻ comprises F^{'1}, Cl⁻, Br⁻, I^{'1}, or a mixture thereof; and each of A′⁺ and A⁺ independently comprise Cs⁺, Rb⁺, CH₃NH₃⁺, CH₃CH₂NH₃⁺, or H(C═NH₂)NH₂⁺, Me(C═NH₂)NH₂⁺, wherein y is 0-1, 0.05-1, 0.1-1, 0.15-1, 0.2-1, 0.25-1, 0.3-1, 0.35-1, 0.4-1, 0.45-1, 0.05-1, 0. 5-1, 0.55-1, 0.6-1, 0.65-1, 0.7-1, 0.75-1, 0.8-1, 0.85-1, 0.9-1, 0.95-1, 0.05-1, 0-0.95, 0-0.9, 0-0.85, 0-0.8, 0-0.75, 0-0.7, 0-0.65, 0-0.6, 0-0.55, 0-0.5, 0-0.45, 0-0.4, 0-0.35, 0-0.3, 0-0.25, 0-0.2, 0-0.15, 0-0.1, 0-0.05, 0.05-0.95, 0.1-0.9, 0.15-0.85, 0.2-0.8, 0.25-0.75, 0.3-0.7, 0.35-0.65, 0.4-0.6, or 0.45-0.55; and A′⁺ and A⁺ are not the same.

In certain embodiments, the perovskite comprises a Formula (CH₃NH₃⁺)(Pb²⁺)(I⁻)₃ or (H(C═NH₂)N₂⁺), (Cs⁺)_{1-y}(Pb²⁺)(I⁻)₃, wherein y is 0-1, 0.05-1, 0.1-1, 0.15-1, 0.2-1, 0.25-1, 0.3-1, 0.35-1, 0.4-1, 0.45-1, 0.05-1, 0. 5-1, 0.55-1, 0.6-1, 0.65-1, 0.7-1, 0.75-1, 0.8-1, 0.85-1, 0.9-1, 0.95-1, 0.05-1, 0-0.95, 0-0.9, 0-0.85, 0-0.8, 0-0.75, 0-0.7, 0-0.65, 0-0.6, 0-0.55, 0-0.5, 0-0.45, 0-0.4, 0-0.35, 0-0.3, 0-0.25, 0-0.2, 0-0.15, 0-0.1, 0-0.05, 0.05-0.95, 0.1-0.9, 0.15-0.85, 0.2-0.8, 0.25-0.75, 0.3-0.7, 0.35-0.65, 0.4-0.6, or 0.45-0.55.

In certain embodiments, the perovskite comprises a Formula (CH₃NH₃⁺)(Pb²⁺)(I⁻)₃, (H(C═NH₂)NH₂⁺)(Pb²⁺)(I⁻)₃, (H(C═NH₂)NH₂⁺)_{0.9}(Cs⁺)_{0.1}(Pb²⁺)(I⁻)₃, or (H(C═NH₂)NH₂⁺)_{0.5}(Cs⁺)_{0.5}(Pb²⁺)(I^{'1})₃.

In certain embodiments, the intragrain impurities comprise PbI₂ and one or more (A⁺)(X⁻) selected from the group consisting of CsI, CH₃NH₃I, H(C═NH₂)NH₂I, CH₃CH₂NH₃I, and Me(C═NH₂)NH₂I. In certain embodiments, the intragrain impurities comprise PbI₂ and one or more (A⁺)(X⁻) selected from the group consisting of CsI, CH₃NH₃I, and H(C═NH₂)NH₂I.

The intragrain impurities can have a surface area less than 200 nm², less than 180 nm², less than 160 nm², less than 120 nm², less than 100 nm², less than 80 nm², less than 60 nm², less than 40 nm², or less than 20 nm². In certain embodiments, the intragrain impurities have a surface area of 1-200 nm², 1-180 nm², 1-160 nm², 1-140 nm², 1-120 nm², 1-100 nm², 1-80 nm², 1-60 nm², 1-40 nm², 1-20 nm², 10-100 nm², 20-100 nm², 30-100 nm², 40-100 nm², 50-100 nm², 60-100 nm², 70-100 nm², 80-100 nm², 90-100 nm², 20-90 nm², 30-80 nm², 40-70 nm², or 50-60 nm².

The type of instrument used to irradiate the perovskite with the electron beam is not particularly limited and the present disclosure contemplates any instrument that is capable of irradiating the perovskite at the power and/or accumulated electron doses described herein. The laser instruments can be be a Santec High Power Tunable Laser TSL-570 Type H, Santec Ultra-Wideband Tunable Laser Full-band TSL, Santec Ultimate Performance Tunable Laser TSL-770, Turn-Key OBIS 405nm Single Mode Laser System, RGB laser system High Beam Quality 532 nm Laser 532 nm-laser-module, Photop 532 nm Diode Laser Model GDL-S-0500-WTS-00, Turn-Key OBIS 633 nm Single Mode Laser System. The electron beam instruments could be SST EBOGEN EG 150, SST Electron beam generators 60 kV/70 kV, SST Mobile EB-Generators with 60 kV, PTR Electron Beam Generator. In certain embodiments, the electron beam is generated by a transmission electron microscope or a scanning transmission electron microscope.

In certain embodiments, the electron beam has a current of 1-10 pA, 1-9 pA, 1-8 pA, 1-7 pA, 1-6 pA, 1-5 pA, 1-4 pA, 1-3 pA, 1-2 pA, 2-10 pA, 3-10 pA, 4-10 pA, 5-10 pA, 6-10 pA, 7 -10 pA, 8-10 pA, 9-10 pA, 2-9 pA, 3-8 pA, 4-7 pA, 5-6 pA, or 4-6 pA. In certain embodiments, the electron beam has a current of about 5 pA.

The intragrain impurities can be irradiated with an accumulated electron dose of at least 1×10² e·Å⁻², at least 1×10³ e·Å⁻², at least 1×10⁴ e·521 ⁻², at least 1×10⁵ e·Å⁻², at least 1.1×10⁵ e·Å⁻², at least 1.2×10⁵ e·Å⁻², at least 1.3×10⁵ e·Å⁻², at least 1.4×10⁵ e·Å⁻², at least 1.5×10⁵ e·Å⁻², at least 2×10⁵ e·Å⁻², at least 2.5×10⁵ e·Å⁻², at least 3×10⁵ e·Å⁻², at least 3.5×10⁵ e·Å^{×2} at least 4×10⁵ e·Å⁻², at least 4.5×10⁵ e·Å⁻², at least 5×10⁵ e·Å⁻², at least 5.5×10⁵ e·Å⁻², at least 6×10⁵ e·Å⁻², at least 6.5×10⁵ e·Å⁻², at least 7×10⁵ e·Å⁻², at least 7.5×10⁵ e·Å⁻², at least 8×10⁵ e·Å⁻², at least 8.5×10⁵ e·Å⁻², at least 9×10⁵ e·Å⁻², at least 9.5×10⁵ e·Å⁻², or at least 1×10⁶ e·Å⁻². In certain embodiments, the intragrain impurities are irradiated with an accumulated electron dose of 1×10⁵ to 1×10⁶ e·Å⁻², 2×10⁵ to 1×10⁶ e·Å⁻², 3×10⁵ to 1×10⁶ e·Å⁻², 4×10⁶ to 1×10⁶ e·Å⁻², 5×10⁵ to 1×10⁶ e·Å⁻², 6×10⁵ to 1×10⁶ e·Å⁻², 7×10⁵ to 1×10⁶ e·Å⁻², 8×10⁵ to 1×10⁶ e·Å⁻², 9×10⁵ to 1×10⁶ e·Å⁻², 1×10⁵ to 9×10⁵ e·Å⁻², 1 ×10⁵ to 8×10⁵ e·Å⁻², 1'10³to 7×10⁵ e·Å⁻², 1×10⁵ to 6×10⁵ e·Å⁻², 1×10⁵ to 5×10⁵ e·Å⁻², 1×10⁵ to 4×10⁵ e·Å⁻², 1×10⁵ to 3×10⁵ e·Å⁻², 1×10⁵ to 2×10⁵ e·Å⁻², 2×10⁵ to 9×10⁵ e·Å⁻², 2×10⁵ to 8×10⁵ e·Å⁻², 3×10⁵ to 8×10⁵ e·Å⁻², 4×10⁵ to 8×10⁵ e·Å⁻², 5×10⁵ to 7×10⁵e·Å⁻², 5×10⁵ to 6×10⁵ e·Å⁻², or 6×10⁵ to 7×10⁵ e·Å⁻².

In instances in which the perovskite is irradiated with a laser beam, the laser can have a power of 100-1,000 mW. 100-900 mW, 100-800 mW, 100-700 mW, 100-600 mW, 100-500 mW, 100-400 mW, 100-300 mW, 100-200 mW, 200˜1,000 mW, 300-1,000 mW, 400-1,000 mW, 500-1,000 mW, 600-1,000 mW, 700-1,000 mW, 800-1,000 mW, 900-1,000 mW, 200-900 mW, 300-800 mW, 400-700 m W, 400-600 mW, 500-600 mW, or 400-500 m W. In certain embodiments, the laser beam has a power of about 500 mW.

The laser beam can have a wavelength of 380-700 nm, 380-650 nm, 380-600 nm, 380-550nm, 380-500 nm, 380-450 nm, or 400-450 nm. In certain embodiments, the laser beam has a wavelength of about 405 nm.

The perovskite can be irradiated with the laser beam for at least 1 minute, at least 2 minutes, at least 3 minutes, at least 4 minutes, at least 5 minutes, at least 6 minutes, at least 7 minutes, at least 8 minutes, at least 9 minutes, at least 10 minutes, at least 15 minutes, at least 20 minutes, at least 25 minutes, at least 30 minutes, at least 60 minutes, at least 90 minutes, or at least 120 minutes.

In certain embodiments, the perovskite is irradiated with the laser beam for 1-120 minutes, 1-90 minutes, 1-60 minutes, 1-30 minutes, 1-25 minutes, 1-20 minutes, 1-15 minutes, 1-10 minutes, 1-9 minutes, 1-8 minutes, 1-7 minutes, 1-6 minutes, 1-5 minutes, 10-90 minutes, 30-90 minutes, or 60-90 minutes.

The perovskite can be irradiated directly or be present in a photovoltaic device, such as a PSC.

Perovskites products of the method described herein exhibit improved photovoltaic properties relative to perovskites. For example, PSCs comprising perovskite products of the method described herein exhibit improved PCE, FF, J_{SC}, and/or V_{OC}.

### In Situ Observation of Intragrain Impurity Annihilation

The experimental flow for performing the in situ STEM observation is schematically illustrated in FIG. 1a and FIG. 5. Briefly, we fabricated a formamidium-cesium (FA-Cs) PSC with the optimal synthesis conditions (details in Methods) and prepared the device cross-section lamella using FIB nanofabrication, immediately followed by the sputtering deposition of a 10 nm thick amorphous carbon layer onto both sides of the lamella (FIG. 5). Then, as illustrated in FIG. 1a, we used a controlled electron dose to trigger the evolution of intragrain microstructure in the PSC cross-section and acquired a sequence of STEM images at different beam irradiations to resolve the perovskite intragrain crystallographic transformation. Note that high energy electron beam is a widely used in situ stimulus for specimen morphology modifications and triggering structure evolutions inside TEM.

FIG. 1b is a low-magnification STEM-HAADF image acquired with a beam current of the electron probe of 10 pA, exhibiting the initial microstructure of the PSC sample. Using energy dispersive spectroscopy (EDS), each layer of this PSC device can be delineated, confirming the sample integrity (FIG. 6a). We then reduced the beam current of the electron probe to 5 pA to acquire high-resolution STEM-HAADF images. The grain interior shows a clear lattice structure. Based on the real-space image and corresponding fast Fourier transform (FFT) pattern (FIG. 1c), this perovskite grain is resolved as an orthorhombic phase (space group Pnma) projected along [100]ₒ direction (FIG. 6b). A close examination of the high-resolution STEM-HAADF image shown in FIG. 1C reveals at least two types of nanoscale intragrain impurity phases, PbI₂ (solid line regions) and non-PbI₂ impurity (dashed line region; later resolved as an immediate phase with OD crystallographic structure), have been populated and distributed within the perovskite grain. The formation of these intragrain impurities may be influenced by several factors, especially for the fabrication and storage conditions. For the FA-Cs perovskite specimen prepared with a much longer annealing time than the optimal condition, a higher density of intragrain impurities can be observed (FIG. 7b). Similarly, the under-annealed FA-Cs perovskite specimen also exhibits an abundance of intragrain impurity nanoclusters (FIG. 8). In addition, the storage of vacuum packed FIBed FA-Cs perovskite device cross-section specimens can also induce the formation of intragrain impurities (FIG. 9). As a result, both the poorly-prepared perovskite films and degraded perovskite specimens will incorporate a considerable density of intragrain impurities, although these intragrain impurity nanoclusters may originate from different sources. FIGS. 10, 11 show more atomic-level details of such intragrain impurities. Nevertheless, this nanoscale phase variation can hardly be identified only from the FFT pattern (FIG. 1d inset) without real-space images, because of the similarity in spatial symmetry of their structures. It is worth noting that the intragrain PbI₂ impurity nanoclusters can also exist in the methylammonium-cesium (MA-Cs) perovskite (FIG. 12c, d), similar to the case of FA-Cs perovskite (FIG. 12a, b), which implies the generality of this intragrain phenomena.

Herein we note that with the protection of amorphous carbon layers, no obvious changes occur in cross-sectional FA-Cs PSC specimens during STEM observation and imaging which only needs a short scanning time of electron probe. This unlocks investigations of dynamic phenomena induced by continuous electron beam irradiation. In this context, an electron probe with a similar 5 pA beam current was used for nano-regions in situ scanning of cross-sectional FA-Cs PSC specimens. FIG. 1d shows an orthorhombic perovskite grain projected along [100]ₒ direction, a

nano-region with PbI₂ (space group R3mH, projected along [110]ₒ direction, marked by solid line as region 2) was selected. With the following continuous scanning of the focused electron probe (average dose rate calculated as 525 e·Å⁻²/s), some remarkable structural evolutions were recorded at the atomic level (FIG. 1d), revealing the unprecedented transformation details from PbI₂ to perovskite phase in the IGIA process. FIG. 13 demonstrates the shrinkage trend of the PbI₂ region with respect to the accumulated electron dose. At first, interestingly, little change occurs on this PbI₂ nanocluster after the first 248 s electron probe scanning (about 1.3×10⁵ e·Å⁻² accumulated dose). This phenomenon further implies the lowest reaction rate with respect to the smallest specific surface area of the PbI₂ nanocluster at the preliminary stage. Subsequently, the shrinkage of the PbI₂ nanocluster accelerates in both directions after the accumulated electron dose exceeds 1.3×10⁵ e·Å⁻² and is finally completely transferred to the perovskite phase. The FFT patterns (FIG. 1d insets) also show no noticeable changes in this process. Although the quantified volume of the PbI₂ region can hardly be obtained only from this projection-view STEM image, a qualitative analysis is possible as the specific surface area is inversely proportional to the volume of the cluster. Therefore, this IGIA process in FA-Cs perovskite should have a reaction rate proportional to the specific surface area. Generally speaking, the initial large cluster with a small specific surface area will exhibit a slower reaction rate. As a result, with the cluster shrinking in this process, the increasing specific surface area will facilitate the reaction propagation. In addition, we found the existence of the PbI₂ nanocluster leads to the remarkable intragrain strain, which may harm the perovskite performance (FIG. 1e). This intragrain strain can be effectively relaxed by the IGIA process (FIG. 1e).

In another case, a nano-region with both PbI₂ and non-PbI₂ impurity phase was selected as shown in FIG. 14. This non-PbI₂ impurity phase can be resolved as a possible zero-dimensional cation-intercalated PbI₆ octahedral with a chemical composition of (FA,Cs)₄PbI₆ (FIG. 11). Although (FA,Cs) 4PbI₆ has not been reported previously as a bulk material, the nano-confinement of this phase within the crystalline perovskite matrix may enable its meta-stability. In this case, the non-PbI₂ impurity phase nanocluster at the top right corner shrinks (region 1) and is then completely transferred to the perovskite phase right after being irradiated by an electron probe (FIG. 14d, i). During this period, the middle PbI₂ nanocluster (region 2) exhibits little evident change, with the left side non-PbI₂ impurity phase nanocluster (region 3) shrinking slightly. After scanning for 479 s, the shrinkage of both regions 2 and 3 begins to accelerate. The prior transformation of region 1 (non-PbI₂ impurity phase) demonstrates the intermediateness of this phase than PbI₂. Besides, the shrinkage rate also tends to accelerate with the keeping decrease of PbI₂ and non-PbI₂ impurity phase areas (FIG. 14i). Note if only from the FFT patterns (insets in FIG. 14), no obvious changes can be identified. The lower shrinkage pace of region 3 than region 1 may be attributed to the much larger size and smaller specific surface area. Besides, we also find the existence of a non-PbI₂ impurity phase will lead to additional intragrain strain (FIG. 15b). Similarly, this intragrain strain can also be effectively relaxed by the IGIA process (FIG. 15d), which may contribute to improved stabilization in the resultant device.

Crystallographic transformation modes for intragrain impurity annihilation. Our in situ observations reveal clear an IGIA of intragrain PbI₂ nanocluster to perovskite phase. As shown in FIG. 1d, the IGIA propagates with the continuous shrinkage of the PbI₂ nanocluster. Interestingly, the IGIA reaction rate also exhibits an obvious specific surface area dependency. This implies an interface-dependent reaction mechanism, that a step-by-step interfacial transition from PbI₂ to perovskite with the intercalation of FA/Cs cations and I anions driven by electron irradiation. To investigate the underlying reaction mechanisms, the atomic-scale structures of PbI₂/perovskite interfaces are resolved by atomic-resolution STEM (FIGS. 2a-c). Each type of interface can be formed between different crystallographic facets of PbI₂ and perovskite phases. This implies a possible divergent reaction barrier and procedure for different orientated interfaces, which is critical for proposing plausible mechanisms. In this regard, we proposed different crystallographic pathways for the IGIA in PSCs, as schematically shown in FIG. 2. To estimate divergent reaction barriers of different IGIA routes, we probed the thermodynamics of the transformation between the interfaces comprised different crystallographic facets of PbI₂ and perovskite phases using first-principles density functional theory. With the detailed atomic information via the STEM imaging, we considered three interfaces originating from the different crystallographic facets between PbI₂ and perovskite, PbI₂ (11̅0)-perovskite (01 1̅), PbI₂ (001)-perovskite (011) and PbI₂ (1̅11̅)-perovskite (001) as the interface transition routes (FIGS. 2b, d, f). We start from the plausible hypothesis that monovalent cation FA/Cs and anion I gradually intercalate between the edge-sharing layers of Pb-I octahedra in PbI₂ driven by electron irradiation, leading to a step-by-step interfacial transition from PbI₂ to perovskite. We manually constructed such a structure of interfaces comprising different proportions of PbI₂ and perovskite, in which the starting mixed PbI₂/perovskite phase contains a higher proportion of PbI₂ and the final mixed PbI₂/perovskite phase contains a lower proportion of PbI₂, demonstrating a step-by-step interfacial transition. We estimated the thermodynamic cost to form an intermediated phase, which is constructed by intercalating FA/Cs and I ions in between the layers of PbI₂ around the interface (FIGS. 2b, d, e). These values provided a theoretical assessment of the reaction barriers of different IGIA routes. We obtain a barrier height of 18.5 meV per atom for the PbI₂ (11̅0) to perovskite (011̅) interfacial transition, 17.3 meV per atom for the PbI₂ (001) to perovskite (011) interfacial transition and 12.4 meV per atom for PbI₂ (1̅11̅) to perovskite (001) interfacial transition, indicating that PbI₂ (1̅11̅)-perovskite (001) interfacial transition was a more favor IGIA pathway with respect to other pathways. In particular, when considering the transformation process of (FA,Cs)PbI₃ perovskites, the barrier heights per formula unit become more relevant, ranging from 60 to 90 meV. We note that our in situ observations also show the possible higher reaction rate around the PbI₂ (1̅11̅)-perovskite (001) interface.

As demonstrated before, the reaction rate in the IGIA process should be strongly related to the specific surface area of the impurity nanoclusters. Although the specific surface area is related to several factors, i.e., the geometrical shape of the nanocluster, the size plays a more important role. For a larger PbI₂ nanocluster (FIG. 16), it takes a longer time to completely transfer to the perovskite phase than the case shown in FIG. 1d. If the PbI₂ nanocluster is further enlarged, this IGIA will be much harder and needs more input energy (FIGS. 17, 18), which makes the generation and expansion of PbI₂ clusters tend to be irreversible in perovskites under operation conditions. Therefore, this IGIA mechanism will be more effective for the nanoscale intermediate non-PbI₂ phase and PbI₂ nanoclusters exist in perovskite grains with external energy input.

### Electronic Structures of Intragrain PbI₂ Impurity-Perovskite Interfaces

To get insight into the impact of interfaces on the performance of devices, we explored the optoelectronic properties using first-principle calculations. Likewise, we considered three interfaces between PbI₂ and perovskite, PbI₂ (11̅0)-perovskite (011), PbI₂ (001)-perovskite (011) and PbI₂ (1̅11̅)-perovskite (001) (see FIGS. 3a-c). For the interface of the PbI₂ (11̅0)-perovskite (011̅), the valence band maximum (VBM) is contributed from both the PbI₂ and perovskite and the conduction band minimum (CBM) is mainly contributed from the perovskite component (FIG. 3a), with slightly more deep states in the band gap. Nevertheless, from the distribution of states in the band gap of PbI₂ (11̅0)-perovskite (011̅) (FIG. 19a), we observed that the state is due to the p states of Pb and delocalized in the perovskite, which is still considered benign. The computed electronic structures and density of states (DOS) of the PbI₂ (001)-perovskite (011) interface is shown in FIG. 3b. It can be seen that both the VBM and CBM are mainly contributed from the perovskite component, in which the VBM is composed of the antibonding I p states and Pb s states, while the CBM is composed of the p states of Pb and I with a majority nonbonding character (FIG. 19b). Obviously, only some shallow states are localized around the band edge and no deep states exist in the band gap, demonstrating that this interface is generally harmless for the optoelectronic properties of relating device. Analogically, the interface of PbI₂ (1̅11̅)-perovskite (001) exhibits similar electronic structures and DOS (FIG. 3c and FIG. 19c), implying that this interface can also be considered benign.

FA/Cs and I ions are intercalated between the layers of PbI₂ around the interface, leading to an interfacial transition from PbI₂ to perovskite driven by external energies. Also, interfaces can serve as sinks for migrating point defects, such as I interstitials and FA/Cs interstitials. To illustrate the effect of point defect-interface interaction on the electronic structures of the interfaces, we considered the addition of I, FA/Cs and Pb into the three interfaces, respectively. As shown in FIG. 3d-f, I interstitials are introduced into the three interfaces. It is found that the excess I at these interfaces all directly lead to localized trap states, mainly originating from the p orbitals of excess I atoms and neighboring I atoms (FIG. 20). Similarly, Pb interstitials will also lead to the localized trap states in the band gap, which are mainly contributed by the p orbitals of Pb and I atoms around the defect (FIGS. 21, 22). For FA/Cs interstitials (FIGS. 23, 24), there are significant localized trap states originating from the p orbitals of Pb and I atoms close to defect exist in the band gap of PbI₂ (001)-perovskite (011) (FIGS. 23b). In contrast, the states stemming from the FA/Cs interstitials at the interfaces of PbI₂ (11̅0)-perovskite (011̅) and PbI₂ (1̅11̅)-perovskite (001) are closer to band edge and exhibit obviously delocalized characteristics (FIGS. 23a, c), indicating FA/Cs interstitials at these two interfaces are generally harmless. Besides, owing to the well-known low formation energies of I vacancies at the surface or grain boundary, we also considered the I vacancies at the three interfaces (FIGS. 25, 26). Similar to I interstitials, I vacancies at the three interfaces all introduce localized trap states, which originated from the p orbitals of Pb and I atoms close to defects. Clearly, most of the common defects could introduce localized trap states in these interfaces, which will be detrimental to the performance of the device. Indeed, through the IGIA process, not only the expansion of intragrain impurities is prevented, but also the trap states formed at interfaces are suppressed by interface transition, demonstrating that the IGIA driven by external energies may be a promising strategy for defects elimination and optimizing the PCE.

### High-Performance PSCs Based on Laser-Induced Intragrain Impurity Annihilation

The atomic-scale insights into the IGIA and its impacts on electronic structures have inspired us to leverage this phenomenon to improve PSCs. As schematically illustrated in FIG. 4a, we then used an optimized scanning laser to illuminate FA-Cs PSCs with a planar device configuration (FTO/TiO₂—SnO₂/perovskite/Spiro-OMeTAD/Au). The processing details are included in the Methods. We acquired STEM images of the PSC cross-section before and after laser treatment. Like the electron beam, scanning laser can also lead to effective IGIA in perovskites (FIG. 4b). In FIG. 4c, the current density-voltage curves of the FA_{0.5}Cs_{0.5}PbI₃ PSC with and without laser-induced IGIA are compared. The treated PSC shows a PCE of 21.3%, with an open-circuit voltage (V_{OC}) of 1.21 V, a short-circuit current density (J_{SC}) of 21.13 mA/cm², a fill factor (FF) of 0.833, demonstrating obvious improvement, as compared with the neatly fabricated PSC (PCE: 18.5%; J_{SC}: 20.37 mA/cm²; V_{OC}: 1.16 V; FF: 78.56%). The J-V hysteretic curves have been acquired (FIG. 27), also showing improvement with the laser-induced IGIA. We also examined the effect of laser healing on the structure and optoelectronic properties of the FA-Cs perovskite film. According to a careful X-ray diffraction (XRD) analysis, we identified a weak characteristic peak of PbI₂ in the pristine FA-Cs perovskite film, which disappears after the laser-induced IGIA process (FIG. 28), consisting with the expected reduction in intragrain impurities coupled with IGIA. In addition, we performed the crystal structure refinement of the XRD patterns (FIG. 29), revealing little impact of laser-induced IGIA on the lattice parameters and crystallite sizes in FA-Cs perovskite films. Besides, both top-view scanning electron microscopy (SEM) and atomic force microscopy (AFM) results (FIGS. 30-31) show little change in the perovskite film surface morphology after the laser-induced IGIA treatment, which implies that the PbI₂ impurity healing may mostly occur inside the perovskite grains. The film after laser-induced IGIA also exhibits higher-intensity steady-state photoluminescent (PL) peaks and longer PL lifetime (FIGS. 32, 33 and 56), confirming the decrease of trap density and thus nonradiative recombination. Besides, the time-resolved photoluminescence (TRPL) spectra obtained from different sites of FA-Cs perovskite film confirm the uniformity of laser-induced IGIA treatment (FIG. 33). The enhancement in the structure and properties of perovskites serves as a solid link between IGIA and device PCE increase. The integrated photocurrent densities (without IGIA: 20.22 mA cm⁻²; with IGIA: 21.08 mA cm⁻²) from the external quantum efficiency (EQE) spectra in FIG. 4d, are consistent with the extracted J_{SC} values from J-V curves. We also examined the statistics of device PCEs. FIG. 34 presents a box chart distribution of PCEs based on 20 individual devices for each case (with and without laser-induced IGIA), demonstrating excellent reproducibility on the PCE improvement. Furthermore, proves the feasibility of laser-healing method for fabricating large-area, high-performance PSCs by presenting a 17.64% PCE, 14.00 cm² solar module consisting 10 cells in series connection (FIG. 4e and FIG. 35b), higher than that (16.13% PCE) of the solar module without the laser-induced IGIA treatment (FIG. 35a). IGIA may be applied to other perovskite compositions. When we started with a FA_{0.9}Cs_{0.1}PbI₃ PSC, laser-induced IGIA can deliver a PCE of 22.9%, with a V_{OC} of 1.15 V, a J_{SC} of 24.88 mA cm⁻², an FF of 0.799, as compared with 21.9% for regular devices (FIG. 36). Besides, with optimized processing conditions applied, the laser-induced IGIA can also be effective on other perovskite systems, such as MAPbI₃, FAPbI₃ and (FA_{0.95}Cs_{0.05}PbI₃)₁₋ₓ(MAPbBr₃)ₓ, as shown in FIGS. 37-39 and 57. Finally, we examined the effect of laser-induced IGIA on the device stabilities of PSCs (FIG. 4f). Two different laser treatment methods were applied. One entails laser-induced IGIA only at the film fabrication stage, while the other involves additional laser treatments during the device storage time. After storing these devices for 2000 hours in the same conditions (25° C., 10% RH in the ambient air), we have seen an improvement in the PCE retention, 57% and 90% for the PSC device without IGIA and with IGIA only at the film fabrication stage, respectively. Strikingly, once the device receives additional laser treatments during the device aging test, it can maintain 96% of the initial PCE after 2000 hours, demonstrating the feasibility of laser treatment for further recovering the performance of PSCs during storage. In addition, the device's thermal stability and operational stability have also been tested for over 1000 h. As shown in FIG. 40, both the thermal stability and operational stability are obviously improved, which can be attributed to the IGIA-coupled strain relaxation as further observed for laser-healed perovskite samples (FIG. 41). It is worth noting that when the laser treatment time is too long (about 10 min), the device performance will also be adversely affected as demonstrated in FIG. 42.

The STEM-DFT-device integrated study described herein has demonstrated the discovery of IGIA phenomena and its potential impact on device advancements. However, it is still important to examine the generality of such discovery. Therefore, to further examine the feasibility of imposing IGIA effects on other perovskite systems, we applied in situ electron probe scanning to an MA-Cs perovskite specimen (MA_{0.5}Cs_{0.5}PbI₃) which contains similar intragrain PbI₂ nanoclusters (FIG. 12). Similarly, these impurities can also be effectively healed to perovskite phase (FIGS. 43, 44), consistent with our observations in FA-Cs perovskite. This result demonstrates the potential generality of external stimuli-driven IGIA in the board perovskite composition space. Furthermore, to rule out the possibility that IGIA results from the incomplete perovskite crystallization, we carry out in situ observation on an over-annealed FA-Cs perovskite specimen (FIG. 7b), and the intragrain PbI₂ nanocluster can be annihilated (FIG. 45). We note that by examining the IGIA reaction stoichiometry, excess FA/Cs cations and halide anions are necessary, which may be derived from the solution processing additive (such as FACI in this work). In the pristine state of as-synthesized perovskite films, these excess ions may be dispersed within the grain boundary regions, which can be activated by external stimuli, thus migrating into the reaction fronts of PbI₂/perovskite transformation. To attest to this, we prepare the (FA,Cs)PbI₃ and (MA,Cs)PbI₃ specimens without the addition of FACI and MACI. As a result, continuous electron probe scanning drives no variation or even gradual expansion of the existing intragrain PbI₂ impurity nanoclusters rather than shrinkage and annihilation (FIGS. 46, 47). Besides, referring to the PSC device fabricated from (FA,Cs)PbI₃ without the addition of FACI, the same laser treatment is found less effective in improving the device stability and PCE recovery (FIG. 48). This implies the possible role of FACI addition in perovskite synthesis on the IGIA effect, which is interesting for further exploration. Moreover, the influence of electron dose rate on the IGIA process is also examined. As shown in FIG. 49, using a smaller 1 pA electron beam current (corresponds to 105 e·Å⁻²/s dose rate), a similar IGIA phenomenon can be observed but a significantly longer irradiation time is required. Therefore, the overall dose for healing the small-size PbI₂ nanoclusters exhibits a similar magnitude which is likely to be independent of the dose rate (FIGS. 43, 44, 49). However, if a significantly larger electron beam current up to 10 pA is adopted, the perovskite structure framework tends to collapse in the irradiated region rather than heal the intragrain PbI₂ nanoclusters (FIG. 50).

In closing, we leverage the atomic-scale in situ STEM methodology to investigate the phase and structural dynamics in PSCs, and we visualize various crystallographic transformation modes of intragrain PbI₂ impurity phases being healed to perovskites with atomic-scale evidence, strikingly in contrast to our intuitive understanding that perovskites always tend to degrade under external stimuli. We further demonstrate that such fundamental findings are translatable to accelerate innovations in processing and treatment methods for achieving more efficient and stable solar cells. We envision that more advanced in situ TEM studies, incorporating atmosphere, temperature and even light conditions, will generate more translatable fundamental discoveries for the advancement of multi-functional perovskite optoelectronics.

### Methods

MHP precursor solution and film synthesis. The FA-Cs mixed MHP (FA_{0.5}Cs_{0.5}PbI₃, MA_{0.5}Cs_{0.5}PbI₃) thin films are prepared according to the method reported earlier. First, 1.33 M MHP precursor solution of FA_{0.5}Cs_{0.5}PbI₃ (MA_{0.5}Cs_{0.5}PbI₃) was prepared by dissolving FAI (MAI), CsI, FACI (MACI) and PbI₂ with ratios of 0.5:0.5:0.5:1 in dimethyl sulfoxide (DMSO). The precursor solutions were stirred at 65° C. for 6 h to be ready for use. Then the perovskite solution was spin-coated in a two-step at 1000 rpm and 5000 rpm for 10 s and 60 s, respectively. During the second step, 380×2 μl ethyl acetate was drop-casted quickly at the 20 and 40 s of the second step. The perovskite film was then heated at 100° C. for 2 min in the glove box and 140° C. for 60 min in ambient condition (RH≈30-40%) to form the FA-Cs mixed MHP thin film. This annealing time is optimized by XRD measurement as shown in FIG. 51. Besides, further SEM images (FIGS. 52, 53), UV-vis spectra (FIG. 54) and performance test (FIG. 55) also confirm 60 min should be the optimal annealing time. The crystallization of FA-Cs MHP is completed after 60 min annealing with less PbI₂ formed than 90 min annealing, this has also been confirmed by STEM observation (FIG. 7). As for the MA_{0.5}Cs_{0.5}PbI₃ thin films, the annealing temperature is 100° C. for 60 min in ambient condition (RH≈30-40%).

Device Fabrication. Fluorine-doped tin oxide (FTO)-coated glass (2.20 mm, 7 Ωsq⁻¹) was used as the substrate for the devices. The compact TiO₂ layer (˜10 nm) was deposited by atomic layer deposition (ALD) for 200 cycles and annealed at 500° C. for 30 min in ambient air. For ALD TiO₂ deposition, titanium (IV) isopropoxide (TTIP) and H₂O as Ti and O sources, respectively. The TTIP precursor was held at 75° C. Pulse/exposure/purge times of 1 s/8 s/25 s was used for the TTIP and 0.1 s/8 s/25 s for H₂O precursor, and the deposition temperature was set to 120° C. On top of the c-TiO₂ layer, SnOx-Cl layer was deposited by spin-coating at a rate of 3000 rpm for 30s from an aged SnCl₄ aqueous solution (1:75 with deionized water by volume), followed by a sintering heat-treatment of 200° C. for 30 min in air and then transferred to the glove box for device fabrication. The perovskite solution was spin-coated in a two-step at 1000 rpm and 5000 rpm for 10 s and 60 s, respectively. During the second step, 380×2 μl ethyl acetate was drop-casted quickly at the 20 and 40 s of the second step. The perovskite film was then heated at 100° C. for 2 min in the glove box and 140° C. for 60 min in ambient condition (RH≈30-40%). Subsequently, the films were treated by laser annealing process. For the surface passivation, 1 mg ml⁻¹ of Methoxy-Phenethylammonium iodide (MeO-PEAI) solution in isopropanol was spin-coated on these perovskite films at 4000 rpm for 30 s. The spiro-OMeTAD chlorobenzene solution (72.3 mg ml⁻¹) with 28.8 μl 4-tert-butylpyridine (96%, Aldrich-Sigma) and 17.5 μl lithium bis (trifluoro-methanesulfonyl) imide (Li-TSFI, Aldrich-Sigma) solution (520 mg Li-TSFI (98%) in 1 ml acetonitrile (99.8%, Aldrich-Sigma) was spin-coated on top of the perovskite film at 3000 rpm for 30 s. The devices were put into a dry-air box (RH<5%) for 12 h. Finally, 80 nm thick Au electrode was thermally evaporated.

For fabricating modules, P1 etching process was pre-patterned on FTO glass (5 cm×5 cm) with a 1064 nm fiber laser (Han's laser). The laser power ratio, laser duty cycle, and laser frequency were 30%, 5%, and 50 kHz, respectively. Then, patterned FTO substrates were cleaned and treated by UV Ozone Cleaner (Ossila) for 15 min. The TiO₂/SnO₂, MeO-PEAI, and Spiro-OMeTAD layers were prepared with the same procedure as presented above. The large-size perovskite film was prepared the same as above. The perovskite solution was spin-coated in a two-step at 1000 rpm and 4000 rpm for 10 s and 60 s, respectively. During the second step, 600×2 μl ethyl acetate was drop-casted quickly at the 20 and 40 s of the second step. The perovskite film was then heated at 100° C. for 2 min in the glove box and 140° C. for 60 min at ambient condition (RH≈30-40%). Subsequently, the film was treated by a laser annealing process. For P2 etching process, the laser used was a 532 nm laser with a laser power ratio of 65%, laser duty cycle of 5%, and laser frequency of 100 kHz. 80 nm thick Au electrodes were thermally evaporated under vacuum to complete the modules fabrication. Finally, P3 etching used the same laser as P2 with a laser power ratio of 50%, laser duty cycle of 5%, and laser frequency of 100 kHz. P4 is an etching procedure for cleaning the edge of the modules, the laser used in P4 is the same as P1 with a laser power ratio of 40%, laser duty cycle of 10%, and laser frequency of 100 KHz.

Testing and laser annealing. XRD spectra were measured by Ultima IV of Rigaku with Cu Kα radiation (1.5406 Å) from 10° to 40° with 0.01° step of scan, speed of scan 10° min⁻¹ (Voltage 45 kV, Current 200 mA). PbI₂ calibration reference standard PDF card (07-0235). The UV-Vis absorbance spectra were measured by QE Pro (Ocean Optics). Steady PL spectra were recorded on QE Pro excited at 460 nm. EQE measurement was calculated using certified incident photon to current conversion efficiency equipment from Enlitech (QE-R). Time-resolved photoluminescence (TRPL) experiments were performed by Steady State and Transient State Fluorescence Spectrometer (HORIBA Nanolog). The testing conditions as the films were photoexcited at 440 nm pulse width ˜60 ps, 3.0 mW/pulse, and emission were collected on the surface side of the film (perovskite/glass substrate) at 760 nm with 5 nm slit size. The lifetime was calculated by bi-exponential fitting with the Expdec2 function Y=A₁exp(−t/τ₁)+A₂exp(−t/τ₂). J-V curves of the as-fabricated PSCs were measured using a SourceMeter (Keithley 2400) under simulated one-sun AM 1.5G 100 mW cm-2 intensity (LED) with a scan rate of 200 mV/s (the voltage step is 20 mV with no delay time) from forward scanning directions in air condition around 25° C. The typical active area of PSCs is 0.09 cm2 defined by a metal mask. The intensity of one-sun AM 1.5G illumination was calibrated using a Si-reference cell certified by the National Renewable Energy Laboratory. For the device stability, the devices were stored in a dry-air box with a relative humidity of 10%. For the laser annealing process, the film is scanned (estimated scanning speed is 2 cm/s) and irradiated from the glass side for 5 minutes at a height of about 70 cm from the film with a laser (XINRUI, laser power is 500 mW, laser wavelength is 405 nm, laser spot size is 0.3 mm and the laser irradiation area is around 10 mm²) after the annealing process. The substrate temperature during laser treatment is 22.8° C. measured by an infrared thermometer.

STEM specimen preparation. The cross-sectional TEM specimens of PSCs were prepared by a dual-beam focused ion beam (FIB) nanofabrication platform (Helios 600i, Thermofisher). A protection layer was first deposited on the top surface of the devices by electron deposition of Pt, followed by etching the surrounding area to form the specimen lamella. The operation voltage of the gallium ion beam is 30 kV and the working current is 0.1 to 24 nA for lamella processing. The lamella was then lifted out from the substrate and in situ transferred to a TEM half grid inside the FIB chamber. The observation area of lamella was thinned to less than 100 nm with 40 to 790 pA gallium ion beam. To minimize the damage induced by ion implantation to sample lamella, a fine milling and polishing process was adopted using a gallium ion beam with accelerating voltage down to 1 kV and 72 pA working current to remove the surface amorphous layer. After FIB preparation and polishing procedures, the as-prepared cross-sectional PSC specimens were transferred to a high vacuum sputter coater for protection layer deposition. Amorphous carbon layers with a thickness of 10 nm were coated on both sides of the cross-section specimen using pulsed carbon evaporation at 8×10⁻⁵ mbar.

Stability testing. For the stability tests, all PSCs were without encapsulation. For storage stability, the devices were stored in a dark environment with a humidity of 10-30%, and the photovoltaic performance of PSCs was measured at intervals. The thermal stability was carried out by repeating the J-V test at intervals for the devices heated at a fixed temperature of 85° C. in a nitrogen glove box. The operational stability was performed using a stability setup (LC Auto-Test 24, Shenzhen Lancheng Technology Co., Ltd.), tested under continuous light illumination and maximum power point tracking (controlled and monitored to be 15° C.). The light source consisted of an array of white LEDs powered by a constant current. Equivalent sun intensities were calibrated using a calibrated Si-reference cell. During aging, the device is connected with a 100 Ohm load resistance. The PSCs were masked and placed inside a sample holder purged with continuous N₂ flow. J-V curves with reverse voltage scans were recorded every 6 h during the whole operational test.

STEM characterization and in situ approach. STEM observations of the device cross-section specimens were carried out in an aberration-corrected STEM microscope (Titan G2 60-300 and Spectra 300, Thermofisher equipped with a field emission gun) with 300 kV electron beam accelerating voltage. The beam current of the electron probe was reduced to 5 pA to minimize the damage to MHP frameworks during atomic resolution imaging. The probe convergence angle was 24.5 mrad, and the angular range of the HAADF detector was from 79.5 to 200 mrad. The dwell time of each pixel during STEM-HAADF image acquisition is 6 μs, and the size of all STEM-HAADF images in this work is 2048×2048 pixel2. For the typical high-resolution STEM-HAADF images illustrated in this work, the frame size is 34.5×34.5 nm². For in situ electron probe continuous scan of regions of interest (ROI) in our experiment, we used 5 pA beam current and 1 μs dwell time for each pixel with scanning pixel size set as 1024×1024 pixel². The scanning frame size is also kept at 24.4×24.4 nm². The average dose rate can be calculated as 525 e·Å⁻²/s.

Computational Methods. All ab initio computations for the periodic systems are performed based on density-functional theory (DFT) methods as implemented in the Vienna ab initio simulation package (VASP 5.4). The projector-augmented wave (PAW) method with the generalized gradient approximation of Perdew-Burke-Ernzerhof (PBEsol) exchange-correlation functional was adopted. The Heyd-Scuseria-Ernzerhof (HSE06, α=0.43) hybrid functional was applied to compute the electronic structure more accurately. The SOC was considered in the calculation due to the inclusion of the heavy metal element Pb. The cut-off energy was set to be 520 eV for structure optimization, and 400 eV for electronic structure calculations. The convergence thresholds for the energy difference and the force were set to be 1×10⁻⁴ eV and 4×10⁻² eV/Å, respectively. The Monkhorst-Pack k-point mesh of 1×1×1 was used for Brillouin zone integration. The supercells of PbI₂ (1̅11̅)-perovskite (001), PbI₂ (001)-perovskite (011) and PbI₂ (11̅0)-perovskite (011̅) are 12.5 Å×12.5 Å×50.7 Å, 15.3 Å×8.8 Å×41.3 Å and 8.8 Å×15.3 Å×48.5 Å, respectively.

What is claimed is:

1. A method of reducing intragrain impurities in a perovskite, the method comprising:
irradiating the perovskite with an energy beam selected from the group consisting of a laser beam and an electron beam thereby reducing the intragrain impurities in the perovskite.

2. The method of claim 1, wherein the intragrain impurities comprise (M²⁺)(X⁻)₂ and (A⁺)(X⁻); and the perovskite comprises a Formula (A⁺)(M²⁺)(X⁻)₃, wherein M²⁺ comprises Pb²⁺, Sn²⁺, Ge²⁺, or a mixture thereof; X⁻ comprises F⁻, Cl⁻, Br⁻, I⁻, or a mixture thereof; and A⁺ comprises Cs⁺, Rb⁺, CH₃NH₃⁺, CH₃CH₂NH₃⁺, H(C═NH₂)NH₂⁺, Me(C═NH₂)NH₂⁺, or a mixture thereof.

3. The method of claim 2, wherein M²⁺ comprises Pb²⁺, X⁻ is Br⁻, I⁻, or a mixture thereof, and A⁺ is Cs⁺, CH₃NH₃⁺, H(C═NH₂)NH₂⁺, or a mixture thereof.

4. The method of claim 2, wherein the intragrain impurities comprise PbI₂ and one or more of CH₃NH₃I, H(C═NH₂)NH₂I, and CsI.

5. The method of claim 2, wherein the intragrain impurities comprise PbI₂ and one or more of CH₃NH₃I, H(C═NH₂)NH₂I, and CsI; and irradiating with the energy beam results in conversion of at least a portion of the intragrain impurities to perovskite.

6. The method of claim 1, wherein the intragrain impurities have an area less than 100 nm².

7. The method of claim 1, wherein the electron beam has a current of 1-10 pA.

8. The method of claim 1, wherein the intragrain impurities receive an accumulated electron dose of at least 1.3×10⁵ e·Å⁻².

9. The method of claim 1, wherein the intragrain impurities have an area less than 100 nm²; and the intragrain impurities receive an accumulated electron dose of at least 1.3×10⁵ e·Å⁻².

10. The method of claim 1, wherein the electron beam has a current of 1-10 pA and the intragrain impurities receive an accumulated electron dose of 1×10⁵ to 1×10⁶ e·Å⁻².

11. The method of claim 1, wherein the electron beam has a current of 1-10 pA and the intragrain impurities receive an accumulated electron dose of 2×10⁵ to 8×10⁵ e·Å⁻².

12. The method of claim 1, wherein the laser beam has a power of 100-1,000 mW and a wavelength of 380-700 nm.

13. The method of claim 12, wherein the perovskite is irradiated with the laser beam for at least one minute.

14. The method of claim 1, wherein the perovskite comprises (CH₃NH₃⁺)(Pb²⁺)(I⁻)₃ or (H(C═NH₂)NH₂⁺)_{y}(Cs⁺)_{1-y}(Pb²⁺)(I⁻)₃, wherein y is 0-1; the intragrain impurities have an area less than 100 nm² and comprise PbI₂ and one or more of CH₃NH₃I, H(C═NH₂)NH₂I, and CsI; and the intragrain impurities receive an accumulated electron dose of at least 1.3×10⁵ e·Å⁻².

15. The method of claim 1, wherein the perovskite comprises (CH₃NH₃⁺)(Pb²⁺)(I⁻)₃ or (H(C═NH₂)NH₂⁺)_{y}(Cs⁺)_{1-y}(Pb²⁺)(I⁻)₃, wherein y is 0-1; the intragrain impurities have an area less than 100 nm² and comprise PbI₂ and one or more of CH₃NH₃I, H(C═NH₂)NH₂I, and CsI; the electron beam has a current of 1-10 pA; and the intragrain impurities receive an accumulated electron dose of 1×10⁵ to 1×10⁶ e·Å⁻².

16. The method of claim 1, wherein the perovskite is (CH₃NH₃⁺)(Pb²⁺)(I⁻), (H(C═NH₂)NH₂⁺)_{y}(Cs⁺)_{1-y}(Pb²⁺)(I⁻)₃, or a mixture thereof, wherein y is 0-1; the intragrain impurities have an area less than 100 nm² and comprise PbI₂ and one or more of CH₃NH₃I, H(C═NH₂)NH₂I, and CsI; and the laser beam has a power of 400-600 mW and a wavelength of 300-500 nm.

17. The method of claim 1, wherein the perovskite is present in a photovoltaic device.

18. The method of claim 1, wherein the perovskite is present in a perovskite solar cell.

19. The method of claim 18, wherein the perovskite solar cell exhibits an improvement in at least one photovoltaic property selected from the group consisting of PCE, FF, J_{SC}, and V_{OC}.
